(19) United States
(12) Patent Application Publication
(10) Pub. No.: US 2026/0366160 A1
(43) Pub. Date: Nov. 19, 2026

(54) PEDESTAL AND SHOWERHEAD WITH RESISTIVE AND RADIATIVE HEATING

(71) Applicant: LAM RESEARCH CORPORATION, Fremont, CA (US)

(72) Inventors: Karl Frederick LEESER, West Linn, OR (US); Vijay Kumar BADAM, Bangalore (IN)

(21) Appl. No.: 19/137,134

(22) PCT Filed: Dec. 12, 2023
(86) PCT No.: PCT/US2023/083634

§ 371 Date: Jun. 9, 2025

Related U.S. Application Data
(60) Provisional application No. 63/432,485, filed on Dec. 14, 2022.

(51) Int. Cl. C23C 16/458; C23C 16/46

(52) U.S. Cl. CPC C23C 16/4586; C23C 16/46

(57) ABSTRACT

A substrate processing system includes a pedestal to support a substrate, a resistive heater disposed in the pedestal to heat the substrate, and a radiative heater disposed in the pedestal to heat the substrate. A substrate processing system includes a showerhead comprising a faceplate and a radiative heater disposed in the showerhead. The faceplate includes a plurality of through holes. The radiative heater includes a plurality of optical elements arranged interstitially with the plurality of through holes of the faceplate. A substrate processing system includes a pedestal to support a substrate, a resistive heater disposed in the pedestal to heat the substrate, a first radiative heater disposed in the pedestal to heat the substrate, a showerhead spaced from the pedestal, and a second radiative heater disposed in the showerhead to heat the substrate.

### CROSS-REFERENCE TO RELATED APPLICATIONS

This application claims the benefit of U.S. Provisional Application No. 63/432,485 filed on Dec. 14, 2022. The entire disclosure of the application referenced above is incorporated herein by reference.

### FIELD

The present disclosure relates generally to substrate processing systems and more particularly to a pedestal and a showerhead with resistive and radiative heating.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically comprises a plurality of processing chambers (also called process modules) to perform deposition, etching, and other treatments of substrates such as semiconductor wafers. Examples of processes that may be performed on a substrate comprise chemical vapor deposition (CVD), plasma enhanced CVD (PECVD), chemically enhanced plasma vapor deposition (CEPVD), atomic layer deposition (ALD), and plasma enhanced ALD (PEALD). Additional examples of processes that may be performed on a substrate comprise etching (e.g., chemical etching, plasma etching, reactive ion etching, etc.).

During processing, a substrate is arranged on a substrate support or a susceptor such as a pedestal, an electrostatic chuck (ESC), and so on in a processing chamber of the substrate processing system. In some processes, during deposition, gas mixtures comprising one or more precursors are introduced into the processing chamber, and plasma may be struck to activate chemical reactions. In other processes, during etching, gas mixtures comprising etch gases are introduced into the processing chamber, and plasma may be struck to activate chemical reactions. A computer-controlled robot is used to transfer substrates from one processing chamber to another in a sequence in which the substrates are to be processed.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. Thermal ALD (T-ALD) is typically performed in a heated processing chamber. The processing chamber is maintained at a sub-atmospheric pressure using a vacuum pump and a controlled flow of an inert gas. The substrate to be coated with a film is placed in the processing chamber and is allowed to equilibrate with the temperature of the processing chamber before starting the ALD process.

### SUMMARY

A substrate processing system comprises a pedestal to support a substrate, a resistive heater disposed in the pedestal to heat the substrate, and a radiative heater disposed in the pedestal to heat the substrate.

In additional features, a substrate processing system comprises a showerhead comprising a faceplate and a radiative heater disposed in the showerhead. The faceplate comprises a plurality of through holes. The radiative heater comprises a plurality of optical elements arranged interstitially with the plurality of through holes of the faceplate.

In additional features, a substrate processing system comprises a pedestal to support a substrate, a resistive heater disposed in the pedestal to heat the substrate, a first radiative heater disposed in the pedestal to heat the substrate, a showerhead spaced from the pedestal, and a second radiative heater disposed in the showerhead to heat the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows a first example of a substrate processing system in which resistive and radiative heating is combined in a pedestal of a processing chamber according to the present disclosure;

FIG. 1B shows a second example of a substrate processing system in which resistive heating is provided in a pedestal of a processing chamber and radiative heating is provided under the pedestal according to the present disclosure;

FIG. 1C shows a third example of a substrate processing system in which resistive heating is provided in a pedestal of a processing chamber and radiative heating is provided in a showerhead according to the present disclosure;

FIG. 1D shows a fourth example of a substrate processing system in which resistive heating is provided in a pedestal of a processing chamber and radiative heating is provided in both the pedestal and a showerhead according to the present disclosure;

FIG. 1E shows a third example of a substrate processing system in which resistive heating is provided in a pedestal of a processing chamber and radiative heating is provided under the pedestal and in a showerhead according to the present disclosure;

FIG. 2 schematically shows an example of the pedestal of FIG. 1A comprising resistive and radiative heaters collocated in the pedestal to heat substrates according to the present disclosure;

FIG. 3 shows the resistive and radiative heaters collocated in the pedestal of FIG. 2 in further detail;

FIG. 4A schematically shows an example of an annular pattern in which the resistive and radiative heaters are collocated in the pedestal of FIG. 2;

FIG. 4B shows the annular pattern in which the resistive and radiative heaters collocated in the pedestal of FIG. 2 in further detail;

FIG. 4C shows an example of zones that can be formed in the radiative heater when the resistive and radiative heaters are collocated in the pedestal of FIG. 2 in the annular pattern shown in FIGS. 4A and 4B;

FIG. 5 schematically shows an example of an annular pattern for the resistive heater and a spoke-like pattern for the radiative heater in which the resistive and radiative heaters are collocated in the pedestal of FIG. 2;

FIG. 6 schematically shows an example of a spoke-like pattern in which the resistive and radiative heaters are collocated in the pedestal of FIG. 2;

FIGS. 7A-7C show examples of segments and zones that can be formed in the radiative heater in the examples shown in FIGS. 2-6;

FIG. 8 schematically shows an example of the pedestal of FIG. 1B in which the resistive heater is embedded in the pedestal and the radiative heater is located under the pedestal to heat substrates according to the present disclosure;

FIG. 9 schematically shows lenses disposed on optical elements in the radiative heater in the example shown in FIG. 8;

FIG. 10 schematically shows an example of optical elements disposed in the radiative heater according to the present disclosure;

FIG. 11 schematically shows an example of a showerhead of FIG. 1C comprising the radiative heater and a pedestal of FIG. 1C to heat substrates according to the present disclosure;

FIG. 12 schematically shows an example of a pedestal of FIG. 1D comprising the resistive heater and a first radiative heater and a showerhead of FIG. 1D comprising a second radiative heater to heat substrates according to the present disclosure;

FIG. 13 schematically shows an example of a pedestal of FIG. 1E comprising the resistive heater with a first radiative heater disposed under the pedestal and shows an example of a showerhead of FIG. 1E comprising a second radiative heater to heat substrates according to the present disclosure;

FIGS. 14 and 15 show an example of a cross-sectional view of the pedestal of FIG. 1A according to the present disclosure;

FIG. 16 shows an example of a block diagram of a system for controlling the resistive and radiative heaters shown in FIGS. 1A-13 according to the present disclosure; and

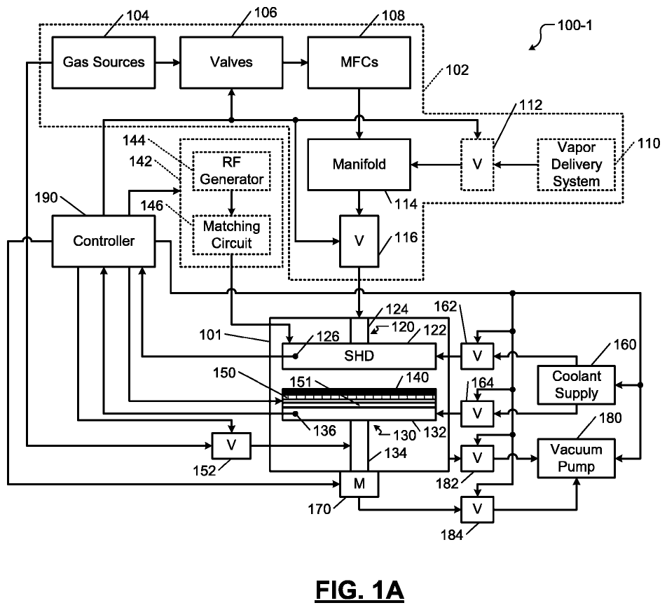

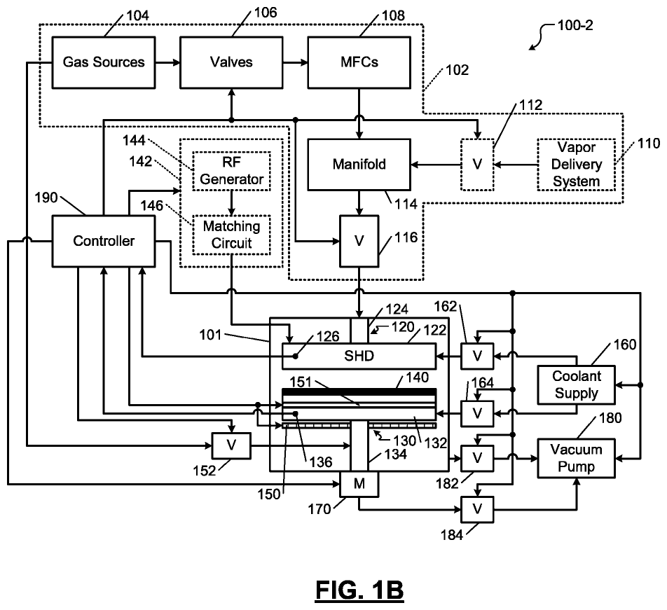

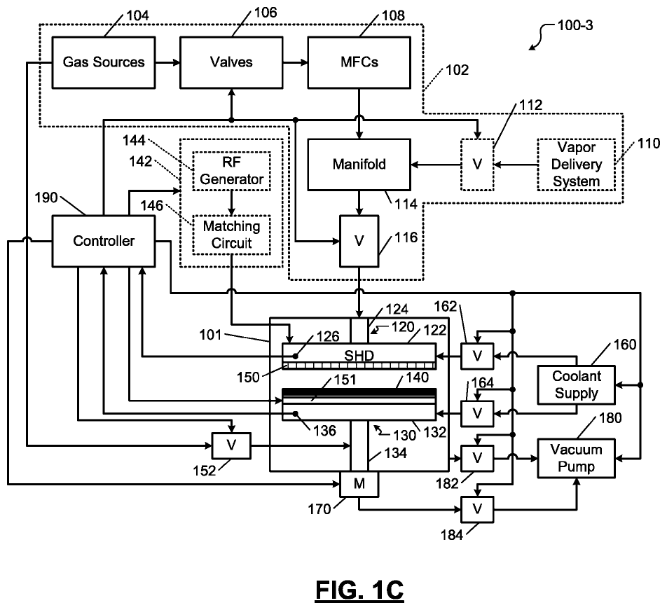

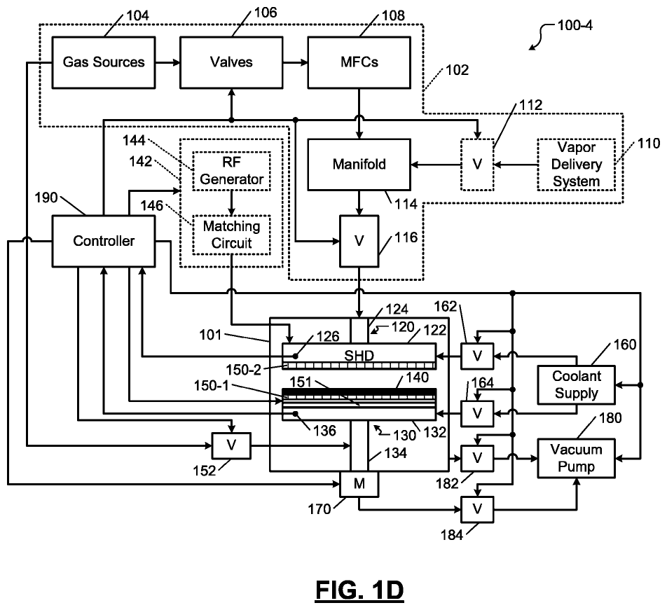

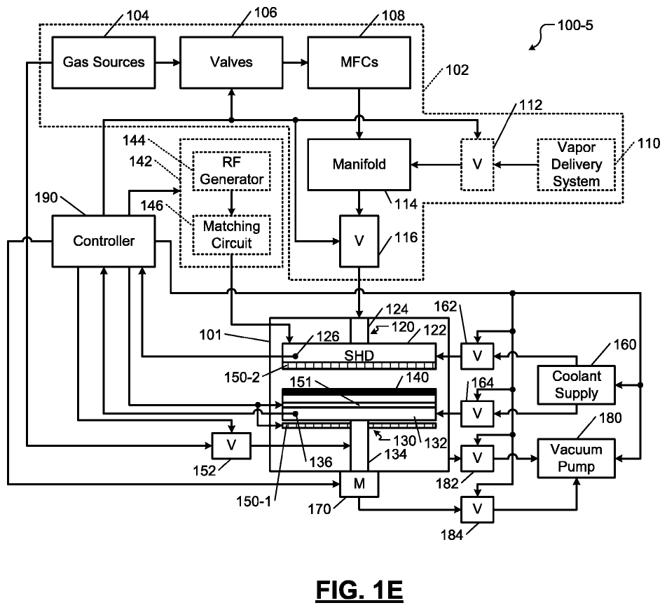

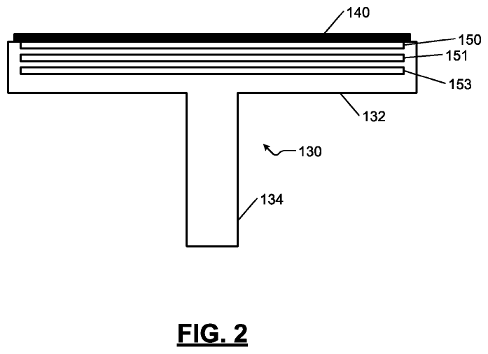

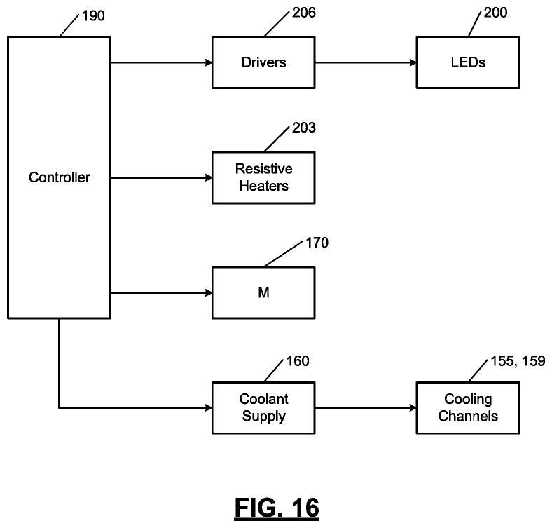

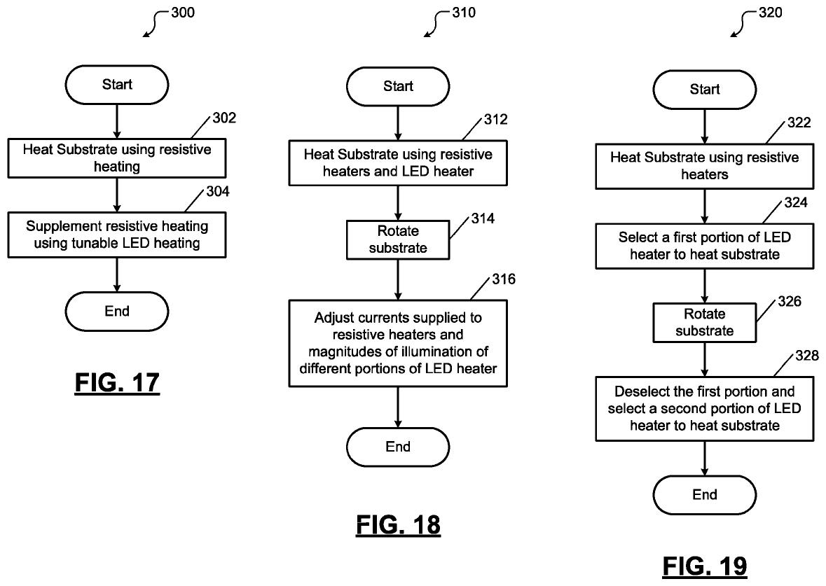

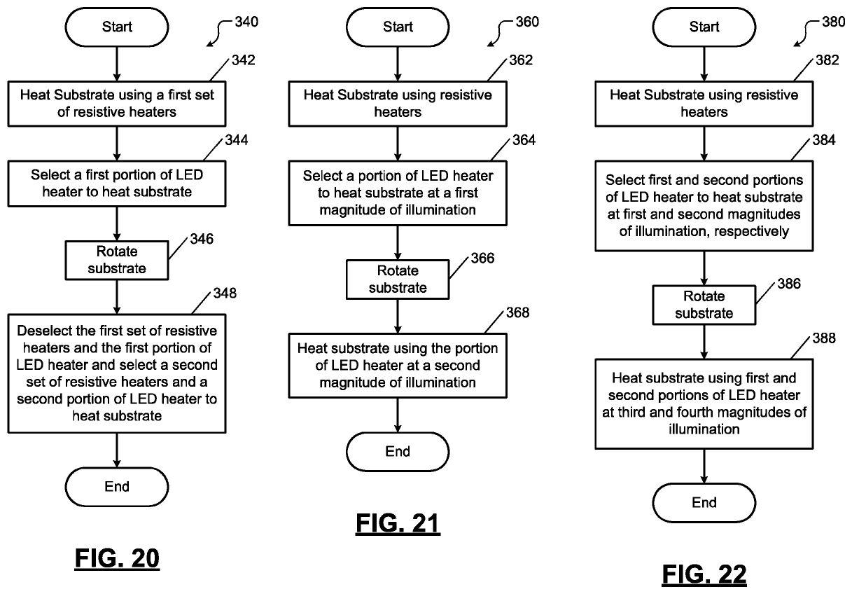

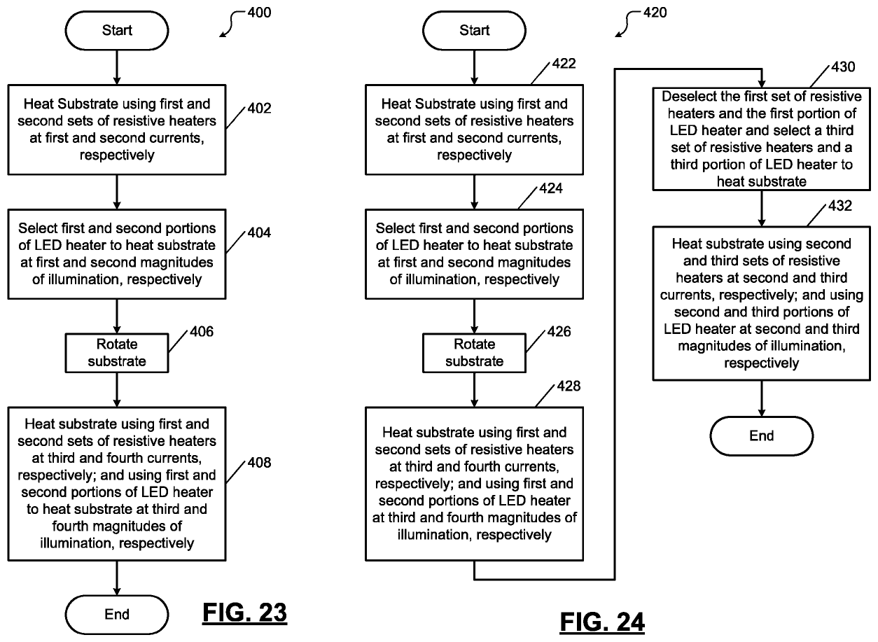

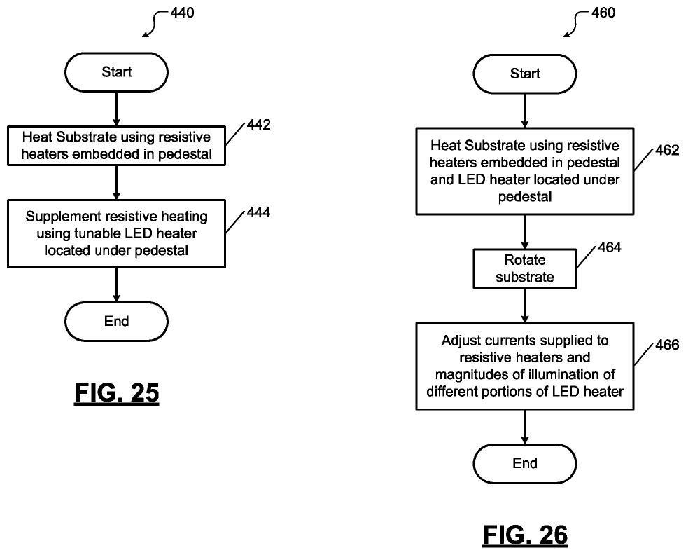

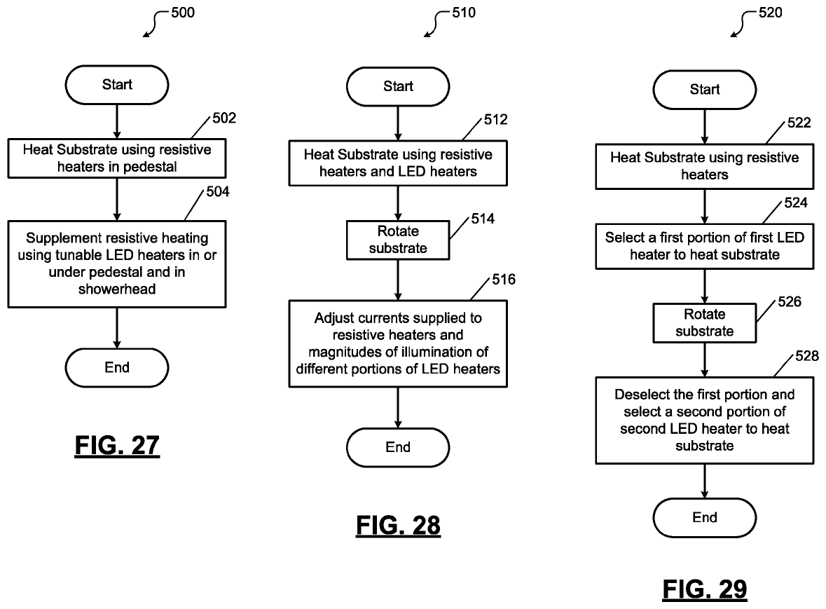

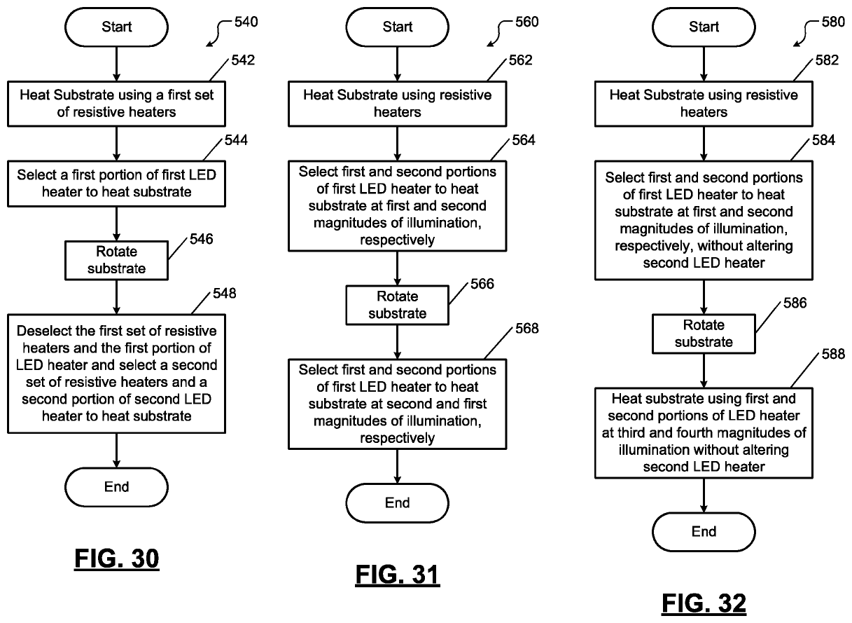

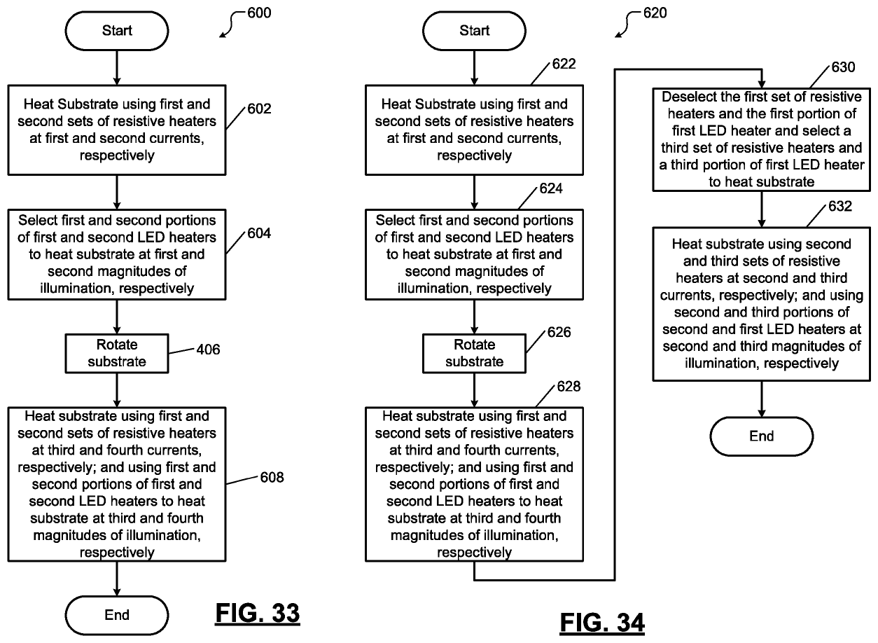

FIGS. 15-34 show examples of methods of heating substrates in the substrate processing systems of FIGS. 1A-1E using the resistive and radiative heaters shown in FIGS. 2-15 and the controller shown in FIG. 16 according to the present disclosure.

In the drawings, reference numbers may be reused to identify similar and/or identical elements.

### DETAILED DESCRIPTION

In some processing chambers, resistive heaters are embedded in a baseplate of a pedestal and are used to heat a substrate arranged on the baseplate of the pedestal. The baseplate comprises a thermally conductive material such as a metallic material. The resistive heaters heat the baseplate. The heat is distributed throughout the baseplate. The heat distributed throughout the baseplate heats the substrate arranged on the baseplate. Resistive heating has a limited ability to tune or adjust localized heating of the substrate in a recipe-controllable manner. For example, the heat from the resistive heaters may not uniformly heat the substrate, which can cause cold spots in the center and/or peripheral regions of the substrate. Such temperature non-uniformity at the center and/or at outer periphery of the substrate reduces yield.

The present disclosure provides systems and methods for improving temperature uniformity throughout the substrate with localized temperature compensation using a combination of resistive heating and LED-based radiative heating. In a first example of resistive and radiative heating according to the present disclosure, resistive and LED-based heaters are collocated in the baseplate of the pedestal comprising a ceramic material. The LED-based heater (hereinafter the LED heater) comprises one of more strings of LEDs. The one of more strings of LEDs may be disposed in the baseplate of the pedestal in an annular concentric pattern that is interleaved with the resistive heaters, which are also arranged concentrically in the baseplate of the pedestal in an annular pattern. Alternatively, the one or more strings of LEDs may be disposed in the baseplate of the pedestal in a spoke-like pattern while the resistive heaters are arranged in the baseplate of the pedestal in an annular pattern. In another implementation, both the resistive heaters and the strings of LEDs may be disposed in an interleaved (e.g., alternating) spoke-like pattern in the baseplate of the pedestal.

In a second example of resistive and radiative heating according to the present disclosure, the resistive and LED-based heaters are not collocated. Instead, the resistive heaters are embedded in the baseplate of the pedestal and the LED heater is disposed under the pedestal. In the second example, the LED heater may comprise lenses disposed on the LEDs. In addition to the resistive heaters, the LED heater heats the pedestal, and the heat from the pedestal heats the substrate. Since the resistive and LED heaters are not collocated, the pedestal may comprise a ceramic material or a metallic material. The resistive heaters in the baseplate of the pedestal and the LEDs in the LED heater may be arranged in an annular pattern, an interleaved (e.g., alternating) spoke-like pattern, or in any combination thereof.

In a third example of resistive and radiative heating according to the present disclosure, the resistive and LED heaters are not collocated. Instead, the resistive heaters are embedded in the baseplate of the pedestal and the LED heater is disposed in the showerhead. In the third example, multiple strings of LEDs may be disposed in the showerhead in an annular concentric pattern. Alternatively, multiple strings of LEDs may be disposed in the showerhead in a spoke-like pattern. The resistive heaters in the baseplate of the pedestal may be arranged in an annular pattern or a spoke-like pattern that may be interleaved (e.g., alternating) with the spoke-like pattern of the LEDs in the LED heater in the showerhead. Since the resistive and LED heaters are not collocated, the pedestal may comprise a ceramic material or a metallic material. The showerhead also may comprise a ceramic material or a metallic material.

In a fourth example of resistive and radiative heating according to the present disclosure, the resistive and LED-based heaters are collocated in the baseplate of the pedestal comprising a ceramic material as in the first example and an additional LED-based heater is disposed in the showerhead as in the third example. Thus, the fourth example is a combination of the first and third examples. In a fifth example of resistive and radiative heating according to the present disclosure, the resistive and LED heaters are not collocated. Instead, the resistive heaters are embedded in the baseplate of the pedestal and the LED heater is disposed under the pedestal as in the second example, and an additional LED-based heater is disposed in the showerhead as in the third example. Thus, the fifth example is a combination of the second and third examples.

In the above examples, the LED strings can be continuous or segmented (zoned). For example, in each circle in the annular pattern, the LEDs may form a single string that can be controlled as a single string. Alternatively, in each circle in the annular pattern, the LEDs may not form a single string. Instead, in each circle in the annular pattern, the LEDs in a string may be divided into segments (zones) that can be controlled individually. Alternatively, LEDs in the circles in the annular pattern may be grouped in quadrants or pie-shaped zones, and each zone or portions thereof may be controlled individually. In the spoke-like pattern, each spoke may comprise one or more strings of LEDs that can be controlled individually or collectively. Alternatively, each spoke may be divided into regions (zones) and LEDs in each region (zone) can be controlled individually. Many other variations are contemplated.

Further, when the resistive and LED heaters are collocated in the baseplate of the pedestal, a cooling channel is provided in the baseplate of the pedestal to control the temperature of the substrate and to also prevent the LEDs from overheating. Additionally, as explained below in detail, the LEDs can be prevented from overheating by controlling the resistive heaters and the LEDs (e.g., LEDs in strings, segments, or zones) individually (e.g., in a temporally staggered manner and with different magnitudes of illumination). Furthermore, in addition to individually controlling the resistive heaters and the LEDs, the overheating of the LEDs can be prevented by rotating the substrate so that different portions of the substrate can be heated by different ones of the resistive heaters and/or the LEDs at different times. In addition, one or more resistive heating elements of the resistive heater may be controlled individually or collectively along with individually or collectively controlling the zones of the LED heater by controlling the magnitudes of illumination of the LEDs.

In the systems and methods of the present disclosure, the resistive heating can be used for coarse or bulk heating of the substrate and the radiative heating by the LEDs can be used for fine or tunable heating of the substrate to compensate for and to eliminate temperature non-uniformity across the substrate. Thus, the LED-based radiative heating can be integrated (combined) within resistive heating to heat specific regions of the substrate in a controlled manner to uniformly heat the substrate. In some examples, the LED-based radiative heating can be used to heat the center region of the substrate and the resistive heating can be used to heat the outer region of the substrate to compensate and eliminate cold spots in the center region of the substrate. In some examples, the LED-based radiative heating can be used to heat the outer (peripheral) region of the substrate and the resistive heating can be used to heat the rest of the substrate to compensate and eliminate cold spots in the outer (peripheral) region of the substrate. A combination of these two features can be used to compensate and eliminate cold spots at the center and outer (peripheral) regions of the substrate. Further, the radiative heating power of the LEDs can be controlled (e.g., modulated) along azimuthal direction to compensate and eliminate azimuthal temperature non-uniformity in the substrate. These and other features of the present disclosure are described below in detail.

### Examples of Substrate Processing Systems

FIG. 1A shows a first example of a substrate processing system (hereinafter the system 100-1) comprising resistive and radiative heating according to the present disclosure. The system 100-1 can be used to process substrates using chemical vapor deposition (CVD), plasma enhanced CVD (PECVD), chemically enhanced plasma vapor deposition (CEPVD), atomic layer deposition (ALD), or plasma enhanced ALD (PEALD) processes. The system 100-1 comprises a processing chamber 101 and a gas distribution system 102. The gas distribution system 102 comprises a plurality of gas sources 104, a plurality of valves 106 connected to the gas sources 104, a plurality of mass flow controllers (MFCs) 108 connected to the valves 106. The gas sources 104 supply various gases comprising process gases, precursors, purge gases, inert gases, cleaning gases, and so on. The MFCs 108 control the mass flow rates of the gases.

In some applications, the gas distribution system 102 further comprises a vapor delivery system 110 to supply one or more vaporized precursors through one or more valves 112. One or more gases from the MFCs 108 and, when used, one or more vaporized precursors are supplied to a mixing manifold 114. The gases or gas mixtures from the mixing manifold 114 are supplied to the processing chamber 101 through a valve assembly (e.g., a pulsed valve manifold or PVM assembly) 116.

The processing chamber 101 comprises a showerhead 120 and a pedestal 130. The showerhead 120 is attached to a top plate of the processing chamber 101. The showerhead 120 receives the gases or gas mixtures from the mixing manifold 114 through the valve assembly 116. The showerhead 120 comprises a base portion 122 and a stem portion 124. The stem portion 124 extends from the center of the base portion 122 and is attached to the top plate of the processing chamber 101. The base portion 122 is cylindrical and comprises a plurality of through holes (not shown) through which the gases or gas mixtures are supplied into the processing chamber 101.

The pedestal 130 comprises a base portion 132 and a stem portion 134. The stem portion 134 is generally cylindrical or can be Y-shaped, with the tapered (i.e., the top of the Y) portion attached to a bottom of the base portion 132. The stem portion 134 extends from the base portion 132 and is attached to the bottom of the processing chamber 101. The base portion 132 is also cylindrical. The stem portion 134 has a smaller diameter than the base portion 132. A substrate 140 is arranged on a top surface of the base portion 132 of the pedestal 130 during processing.

While not shown, the base portion 132 of the pedestal 130 may comprise lift pins to hold, lower, and raise the substrate 140 relative to the base portion 132 of the pedestal 130. Optionally, a shaft (shown and described below) extending through the stem portion 134 and the base portion 132 of the pedestal 130 may be used to hold, lower, and raise the substrate 140 relative to the base portion 132 of the pedestal 130. The lift pins and the shaft can be used in combination to hold, lower, and raise the substrate 140 relative to the base portion 132 of the pedestal 130.

The substrate 140 may be clamped to the base portion 132 using one of many clamping schemes. Examples of the clamping schemes comprise vacuum clamping, electrostatic clamping, and mechanical clamping. An example of the pedestal 130 comprising vacuum clamping is shown and described below. Any of the pedestals shown and described below can be used as the pedestal 130 in the processing chamber 101.

The base portion 132 comprises an LED heater 150 and a resistive heater 151 to heat the substrate 140 as shown and described below in detail. For example, the resistive heater 151 may comprise one or more resistive heating elements (shown and described below in detail). The resistive heater 151 heats the base portion 132, which in turn heats the substrate 140. The resistive heater 151 provides coarse heating while the LED heater 150 provides fine (tunable) heating as described below in detail.

The LED heater 150 comprises an array of optical elements (e.g., LEDs) and a transparent window (shown and described below). Through the window, light from the optical elements in the LED heater 150 is incident on a bottom surface of the substrate 140 to heat the substrate 140. Since the LED heater 150 heats the substrate by radiation from the optical elements (i.e., since the LED heater 150 provides radiative heating by emitting light to optically heat the substrate 140), the LED heater 150 can also be called a radiative heater 150.

The substrate 140 may be heated while being held above the LED heater 150 (e.g., by lift pins that pass through the LED heater 150 or by the shaft). The substrate 140 may be heated when the substrate 140 rests on the LED heater 150 without being clamped (e.g., on mesas on a top surface of the base portion 132, not shown). The substrate 140 may be heated when the substrate 140 rests on the LED heater 150 upon being clamped to the pedestal 130 using any of the clamping methods. The LEDs in the LED heater 150 emit light having wavelengths selected preferably between 530 nm and 1000 nm for optical heating of the substrate 140.

A purge gas (e.g., an inert gas) from one of the gas sources 104 is supplied through a valve 152 to the stem portion 134. The purge gas flows radially over and across the window of the LED heater 150 to clean the window and maintain the transparency of the window as explained below in detail. An example of the pedestal 130 comprising the LED heater 150 and employing a purging scheme is shown and described below with reference to subsequent figures.

In some applications (e.g., in PECVD and PEALD processes), plasma may be used to process the substrate 140. The system 100-1 comprises a radio frequency (RF) system 142 used to generate plasma in the processing chamber 101. The RF system 142 comprises a RF generator 144 and a matching circuit 146. The RF system 142 supplies RF power to the showerhead 120 while the pedestal 130 is grounded. Alternatively, while not shown, the RF power can be supplied to the pedestal 130 while the showerhead 120 is grounded. The RF power activates the gases or gas mixtures supplied through the showerhead 120 and generates plasma between the showerhead 120 and the substrate 140 arranged on the pedestal 130.

The showerhead 120 and the pedestal 130 comprise temperature sensors 126, 136 to sense the temperatures of the showerhead 120 and the pedestal 130. The showerhead 120 and the pedestal 130 comprise cooling channels (now shown). A coolant is circulated through the cooling channels to control the temperatures of the showerhead 120 and the pedestal 130. A coolant supply 160 may supply the coolant to the cooling channels in the showerhead 120 and the pedestal 130 via valves 162, 164.

One or more actuators generally shown at 170 may be used to move the pedestal 130 relative to the showerhead 120. One of the actuators 170 may also be used to move and rotate a shaft (shown and described below in detail) that passes through the stem portion 134 of the pedestal 130 to lift and rotate the substrate 140. The purge gas used to clean the window of the LED heater 150 is supplied through the valve 152 via a conduit in the shaft as shown and described below in detail.

A vacuum pump 180 is connected to the bottom of the processing chamber 101 through a valve 182. The vacuum pump 180 is used to maintain vacuum in the processing chamber 101 and to evacuate reactants and process byproducts from the processing chamber 101. Additionally, when vacuum clamping is used, the vacuum pump 180 is connected to the stem portion 134 of the pedestal 130 through a valve 184. The vacuum pump 180 maintains vacuum through an annular volume around the shaft in the stem portion 134 of the pedestal 130 (shown and described below) to clamp the substrate 140 to the pedestal 130.

In addition, the stem portion 134 comprises a conduit (shown and described below) through which electrical connections are provided to various electrical elements disposed in the base portion 132 of the pedestal 130. For example, the electrical elements comprise the resistive heater 151, the LED heater 150, the temperature sensors 126, 136, and other electrical elements (e.g., clamping electrodes shown and described below) disposed in the base portion 132 of the pedestal 130.

A controller 190 controls the various elements of the system 100-1 (e.g., the gas distribution system 102, the valves, the RF system 142, the resistive heater 151, the LED heater 150, the coolant supply 160, the actuators 170, the vacuum pump 180, etc.). The controller 190 receives data from the temperature sensors 126, 136 and controls the temperatures of the showerhead 120 and the pedestal 130 by controlling the resistive heater 151, the LED heater 150, and the coolant supply 160. These and other features of the system 100-1 are described below in further detail.

FIG. 1B shows a second example of a substrate processing system (hereinafter the system 100-2) comprising resistive and radiative heating according to the present disclosure. The system 100-2 is identical to the system 100-1 shown in FIG. 1A except that the LED heater 150 is disposed below the pedestal 130 instead of in the base portion 132 of the pedestal 130. The LED heater 150 heats the base portion 132 of the pedestal 130, which is also heated by the resistive heater 151. The resistive heater 151 provides coarse heating while the LED heater 150 provides fine (tunable) heating as described below in detail. The combined heat from the resistive heater 151 and the LED heater 150 is used to heat the substrate 140. All other elements of the system 100-2 shown in FIG. 1B that are identical to the system 100-1 shown in FIG. 1A are not described again for brevity.

FIG. 1C shows a third example of a substrate processing system (hereinafter the system 100-3) comprising resistive and radiative heating according to the present disclosure. The system 100-3 is identical to the system 100-1 shown in FIG. 1A except that the LED heater 150 is disposed in the showerhead 120 instead of in the base portion 132 of the pedestal 130. The LED heater 150 in the showerhead 120 heats the substrate 140 from the top of the substrate 140. The resistive heater 151 in the base portion 132 of the pedestal 130 heats the substrate 140 from the bottom of the substrate 140. The resistive heater 151 provides coarse heating while the LED heater 150 provides fine (tunable) heating as described below in detail. The combined heat from the resistive heater 151 and the LED heater 150 is used to heat the substrate 140. All other elements of the system 100-3 shown in FIG. 1C that are identical to the system 100-1 shown in FIG. 1A are not described again for brevity. The systems 100-1, 100-2, and 100-3 are collectively called the systems 100.

FIG. 1D shows a fourth example of a substrate processing system (hereinafter the system 100-4) comprising resistive and radiative heating according to the present disclosure. The system 100-4 is a combination of the systems 100-1 and 100-3 shown in FIGS. 1A and 1C. Specifically, in the system 100-4 shown in FIG. 1D, a first LED heater 150-1, which is identical to the LED heater 150 of the system 100-1 shown in FIG. 1A, is disposed in the base portion 132 of the pedestal 130. Additionally, a second LED heater 150-2, which is identical to the LED heater 150 of the system 100-3 shown in FIG. 1C, is disposed in the showerhead 120. The resistive heater 151 and the first LED heater 150-1 in the base portion 132 of the pedestal 130 heat the substrate 140 from the bottom of the substrate 140. The LED heater 150-2 in the showerhead 120 heats the substrate 140 from the top of the substrate 140. The resistive heater 151 provides coarse heating while the LED heaters 150-1 and 150-2 provide fine (tunable) heating as described below in detail. The combined heat from the resistive heater 151 and the LED heaters 150-1 and 150-2 is used to heat the substrate 140. All other elements of the system 100-4 shown in FIG. 1D that are identical to the systems 100-1 and 100-3 shown in FIGS. 1A and 1C are not described again for brevity.

FIG. 1E shows a fifth example of a substrate processing system (hereinafter the system 100-5) comprising resistive and radiative heating according to the present disclosure. The system 100-5 is a combination of the systems 100-2 and 100-3 shown in FIGS. 1B and 1C. Specifically, in the system 100-5 shown in FIG. 1E, a first LED heater 150-1, which is identical to the LED heater 150 of the system 100-2 shown in FIG. 1B, is disposed in the base portion 132 of the pedestal 130. Additionally, a second LED heater 150-2, which is identical to the LED heater 150 of the system 100-3 shown in FIG. 1C, is disposed in the showerhead 120. The resistive heater 151 and the first LED heater 150-1 in the base portion 132 of the pedestal 130 heat the substrate 140 from the bottom of the substrate 140. The LED heater 150-2 in the showerhead 120 heats the substrate 140 from the top of the substrate 140. The resistive heater 151 provides coarse heating while the LED heaters 150-1 and 150-2 provide fine (tunable) heating as described below in detail. The combined heat from the resistive heater 151 and the LED heaters 150-1 and 150-2 is used to heat the substrate 140. All other elements of the system 100-5 shown in FIG. 1E that are identical to the systems 100-2 and 100-3 shown in FIGS. 1B and 1C are not described again for brevity. The systems 100-1, 100-2, 100-3, 100-4, and 100-5 are collectively called the systems 100.

### First Example of Resistive and Radiative Heating

FIG. 2 schematically shows a first example of resistive and radiative heating according to the present disclosure. In the first example, the resistive heater 151 and the LED heater 150 are disposed in the base portion 132 of the pedestal 130. The pedestal 130 comprises a ceramic material. The LED heater 150 may be arranged above the resistive heater 151 and may be more proximate to the substrate 140 than the resistive heater 151. In some examples shown and described below, the resistive heater 151 and the LED heater 150 may be coplanar. A cooling channel 153 is arranged under the resistive heater 151 in the base portion 132 of the pedestal 130. The coolant from the coolant supply 160 (shown in FIG. 1A) flows through the cooling channel 153. Various configurations and arrangements of the resistive heater 151 and the LED heater 150 in the base portion 132 of the pedestal 130 are shown and described below in detail with reference to subsequent figures.

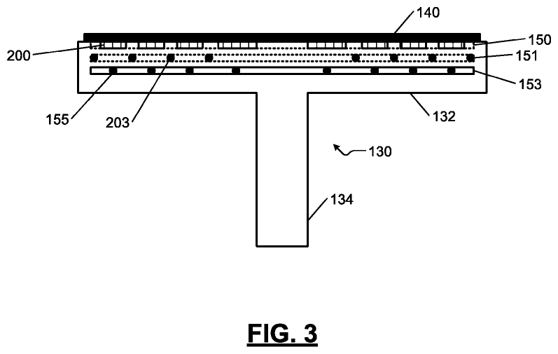

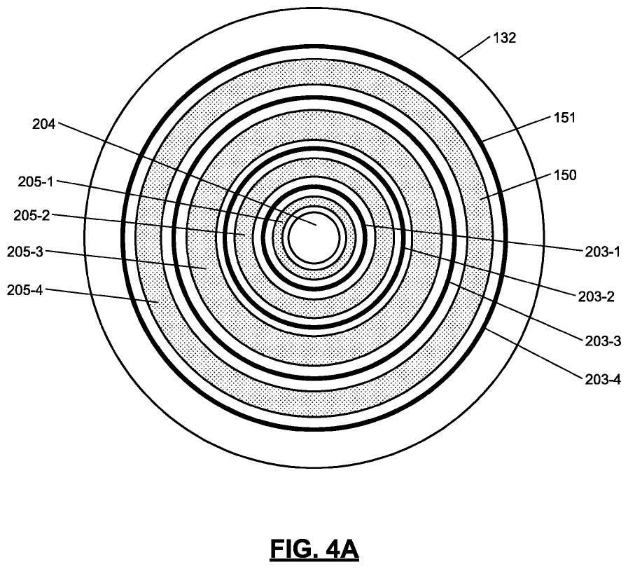

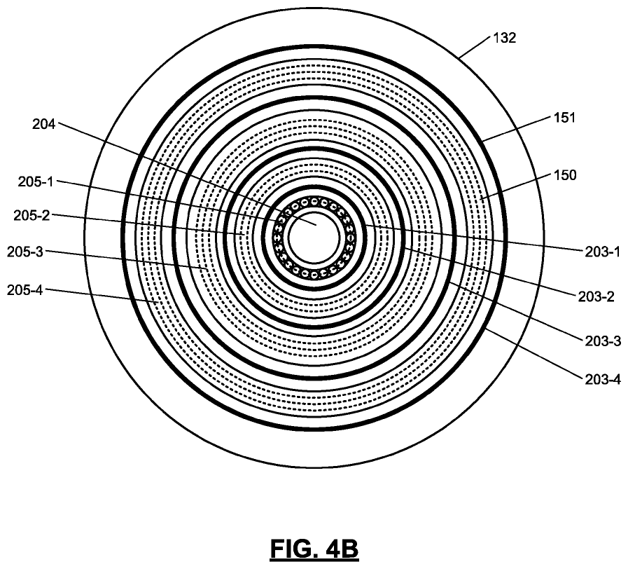

FIG. 3 shows the LED heater 150, the resistive heater 151, and the cooling channel 153 in further detail. The LED heater 150 comprises LEDs 200. The LEDs 200 may be arranged in LED strings in many ways. For example, the LEDs 200 may be arranged in concentric circles, in a poke-like manner, in pie-shaped zones, and so on. Various configurations and arrangements of the LEDs 200 in the LED heater 150 and additional structural details (e.g., a window) are shown and described below in detail with reference to subsequent figures.

The resistive heater 151 may comprise one or more resistive heating elements 203. For example, the resistive heating elements 203 may be arranged in an annular concentric pattern, in a spoke-like pattern, in pie-shaped zones, and so on. Various configurations and arrangements of the resistive heating elements 203 in the resistive heater 151 are shown and described below in detail with reference to subsequent figures. The cooling channel 153 may comprise one or more conduits 155. For example, the conduits 155 may be arranged an annular concentric pattern, in a spiral pattern, and so on. The coolant supplied by the coolant supply 160 (shown in FIG. 1A) flows through the conduits 155 of the cooling channel 153. The cooling channel 153 controls the temperature of the pedestal 130. The cooling channel 153 prevents the LED heater 150 in the base portion 132 of the pedestal 130 from overheating.

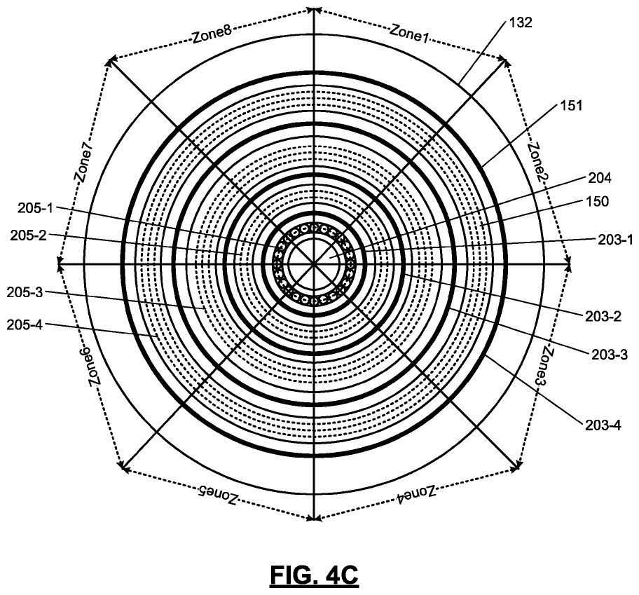

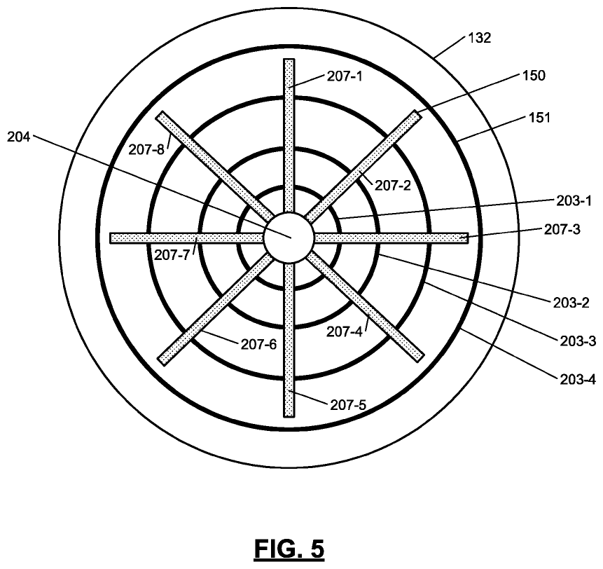

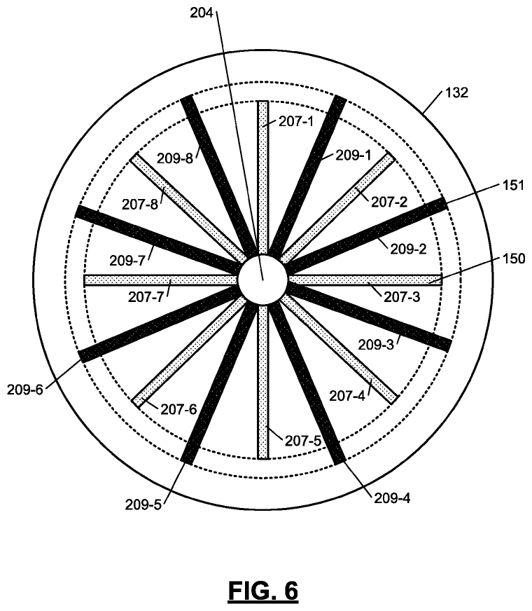

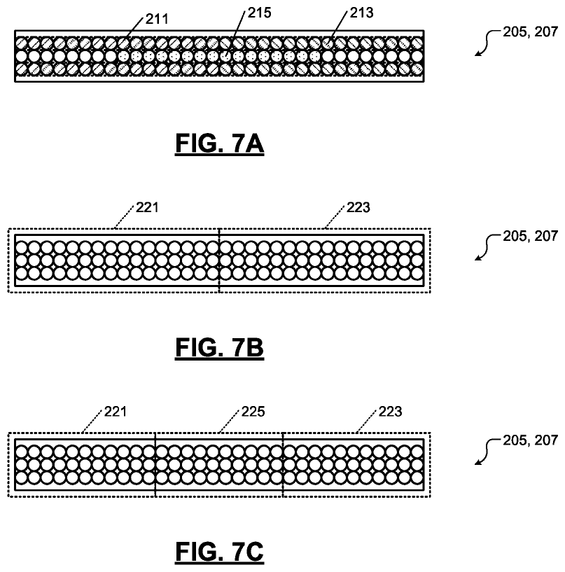

FIGS. 4A-4C show examples of different configurations and arrangements of the LEDs 200 in the LED heater 150 and of the resistive heating elements 203 in the resistive heater 151 in the base portion 132 of the pedestal 130. FIGS. 4A-4C show top views of the LED heater 150 and the resistive heater 151 disposed in the base portion 132 of the pedestal 130. The LED heater 150 may be disposed above the resistive heater 151 in the base portion 132 of the pedestal 130. Alternatively, the LED heater 150 and the resistive heater 151 disposed in the base portion 132 of the pedestal 130 may be coplanar.

FIG. 4A schematically shows an example of an annular concentric pattern in which the LEDs 200 in the LED heater 150 and of the resistive heating elements 203 in the resistive heater 151 are arranged in the base portion 132 of the pedestal 130. Specifically, the LEDs 200 in the LED heater 150 are arranged in one or more concentric groups of LED strings 205-1, 205-2, 205-3, 205-4 (collectively called the groups 205 of LEDs 200 in the LED heater 150) in the base portion 132 of the pedestal 130. The resistive heating elements 203 in the resistive heater 151 are also arranged in an annular concentric pattern in the base portion 132 of the pedestal 130 as shown at 203-1, 203-2, 203-3, 203-4 (collectively called the resistive heating elements 203 in the resistive heater 151).

The LED strings in the groups 205 of LED strings in the LED heater 150 and the resistive heating elements 203 in the resistive heater 151 are arranged in the annular concentric pattern in a non-overlapping manner in the base portion 132 of the pedestal 130. For example, the LED strings in the groups 205 of LED strings in the LED heater 150 and the resistive heating elements 203-1, 203-2, 203-3, 203-4 in the resistive heater 151 are arranged in an alternating (interleaved) pattern from an inner diameter (ID) of the base portion 132 of the pedestal 130 to an outer diameter (OD) of the base portion 132 of the pedestal 130.

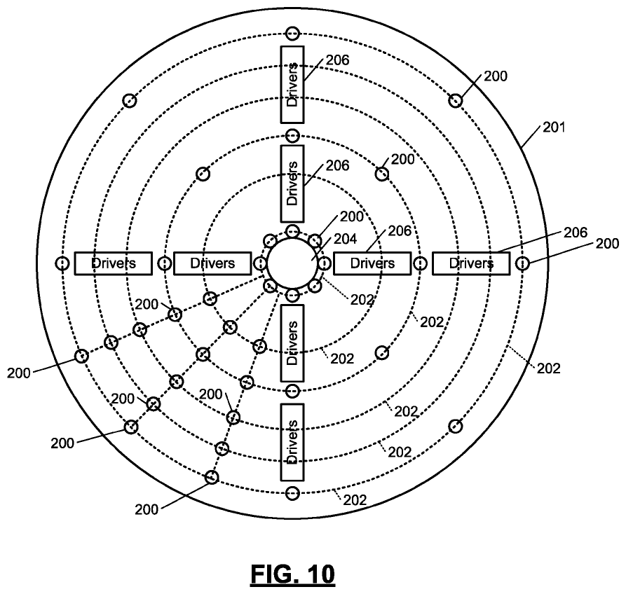

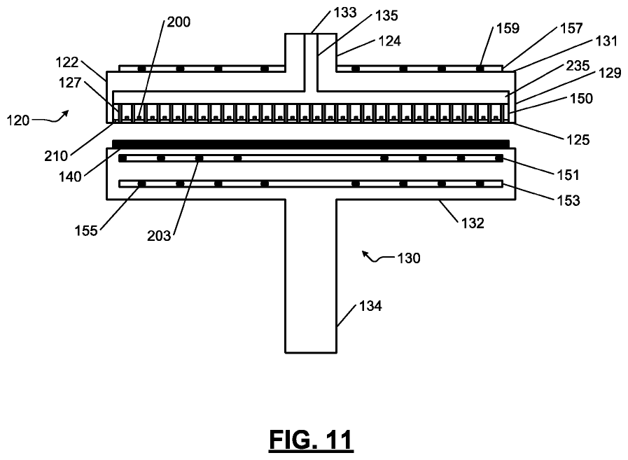

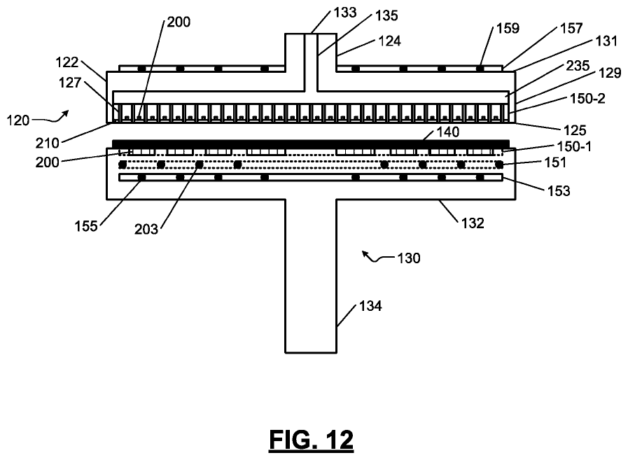

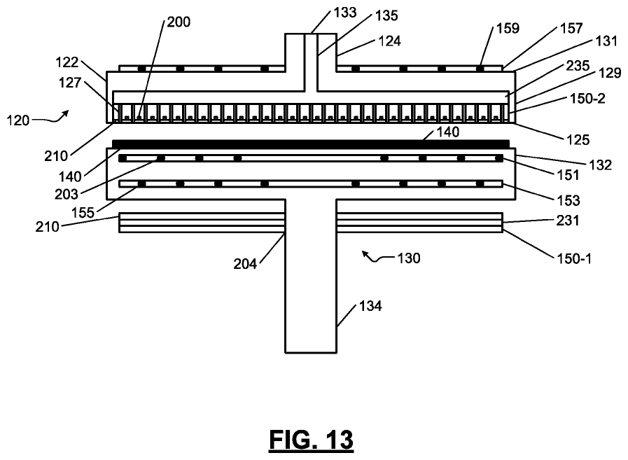

FIG. 4B shows the annular concentric pattern in which the LEDs 200 in the LED heater 150 and of the resistive heating elements 203 in the resistive heater 151 are arranged in the base portion 132 of the pedestal 130 in further detail. For example, each group 205 of LED strings may comprise one or more strings of LEDs 200. Further, in each group 205 of LED strings, the one or more strings of LEDs 200 may be segmented and arranged in zones as shown and described below with reference to FIGS. 7A-7C. In each group 205 of LED strings, the segments and zones can be individually controlled as shown and described below with reference to subsequent figures. As used herein, the segments are portions of the LED strings, and the zones are groups of portions of the LED strings. Additionally, the resistive heating elements 203-1, 203-2, 203-3, 203-4 in the resistive heater 151 can also be individually controlled in combination with individually controlling the segments and zones in each group 205 of LED strings as shown and described below with reference to subsequent figures.

Throughout the present disclosure, controlling the LEDs 200 and controlling the resistive heating elements 203 includes controlling the amount of current supplied to the LEDs 200 and the resistive heating elements 203. The amount of current can range from zero, which turns off the corresponding LEDs 200 and the corresponding resistive heating elements 203, to any value greater than zero, which controls the amount of radiating and resistive heat supplied by the corresponding LEDs 200 and the corresponding resistive heating elements 203.

FIG. 4C shows that the groups 205 of LED strings in the LED heater 150 can be divided into pie shaped zones (e.g., into zones Zone1 through Zone8 as shown). Each zone can be individually controlled as shown and described below with reference to subsequent figures. Further, portions of the groups 205 in each zone can also be individually controlled as shown and described below with reference to subsequent figures. In some examples, the groups 205 of LED strings in the LED heater 150 can be divided into radially overlapping zones as shown and described below with reference to FIGS. 7A-7C. Further, in each portion of the groups 205, the one or more strings of LEDs 200 may be segmented as shown and described below with reference to FIGS. 7A-7C. The segments, zones, and portions of the LED strings can be individually controlled as shown and described below with reference to subsequent figures. Additionally, the resistive heating elements 203-1, 203-2, 203-3, 203-4 in the resistive heater 151 can also be individually controlled in combination with individually controlling the segments and zones in each group 205 of LED strings as shown and described below with reference to subsequent figures.

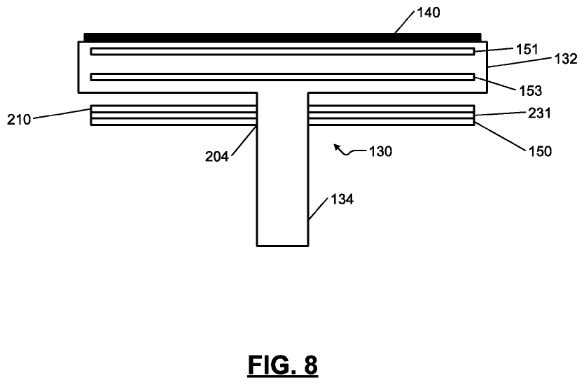

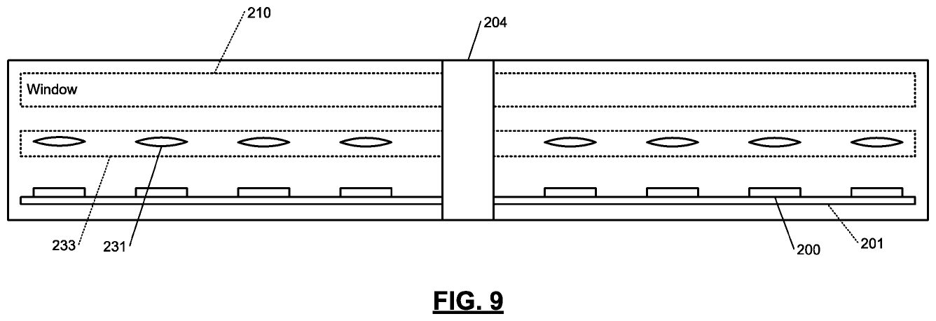

FIGS. 5 and 6 show additional examples of different configurations and arrangements of the LEDs 200 in the LED heater 150 and of the resistive heating elements 203 in the resistive heater 151 disposed in the base portion 132 of the pedestal 130. FIG. 5 shows that the resistive heating elements 203 of the resistive heater 151 are arranged in the same annular concentric pattern shown in FIGS. 4A-4C. However, the LEDs 200 in the LED heater 150 are arranged in a spoke-like pattern. FIG. 6 shows that both the resistive heating elements 203 of the resistive heater 151 and the LEDs 200 in the LED heater 150 are arranged in a spoke-like pattern. FIGS. 5 and 6 show top views of the LED heater 150 and the resistive heater 151 disposed in the base portion 132 of the pedestal 130. The LED heater 150 may be disposed above the resistive heater 151 in the base portion 132 of the pedestal 130 as shown in FIG. 5. Alternatively, the LED heater 150 and the resistive heater 151 may be coplanar as shown in FIG. 6. In these different configurations and arrangements of the resistive heater 151 and the LED heater 150, the arrangement of the cooling channel 153 in the base portion 132 of the pedestal 130 relative to the resistive heater 151 and the LED heater 150 remains as shown and described above with reference to FIGS. 2 and 3.

In FIG. 5, the resistive heating elements 203-1, 203-2, 203-3, 203-4 in the resistive heater 151 (collectively called the resistive heating elements 203 in the resistive heater 151) are arranged in the annular pattern in the base portion 132 of the pedestal 130. The LEDs 200 in the LED heater 150 are arranged in one or more spoke-like radially extending groups of LED strings 207-1, 207-2, . . . , 207-8 (collectively called the groups 207 of LEDs 200 in the LED heater 150) in the base portion 132 of the pedestal 130. The groups 207 of LEDs 200 in the LED heater 150 extend radially from the ID of the base portion 132 of the pedestal 130 to the OD of the base portion 132 of the pedestal 130.

For example, each group 207 of LED strings may comprise one or more strings of LEDs 200 that extend radially from the ID of the base portion 132 of the pedestal 130 to the OD of the base portion 132 of the pedestal 130. Further, in each group 207 of LED strings, the one or more strings of LEDs 200 may be segmented and arranged in zones as shown and described below with reference to FIGS. 7A-7C. In each group 207 of LED strings, the segments and zones can be individually controlled as shown and described below with reference to subsequent figures. In some examples, the groups 207 of LED strings in the LED heater 150 can be divided into radially overlapping zones as shown and described below with reference to FIGS. 7A-7C. Additionally, the resistive heating elements 203-1, 203-2, 203-3, 203-4 in the resistive heater 151 can also be individually controlled in combination with individually controlling the segments and zones in each group 207 of LED strings as shown and described below with reference to subsequent figures.

In FIG. 6, the LEDs 200 in the LED heater 150 are arranged in one or more spoke-like radially extending groups of LED strings 207-1, 207-2, . . . , 207-8 (collectively called the groups 207 of LEDs 200 in the LED heater 150) in the base portion 132 of the pedestal 130 as shown in FIG. 5. The resistive heater 151 comprises resistive heating elements 209-1, 209-2, . . . , 209-8 (collectively called the resistive heating elements 209 in the resistive heater 151) in the base portion 132 of the pedestal 130. The resistive heating elements 209 in the resistive heater 151 are also arranged in a spoke-like radially extending pattern similar to the groups 207 of LEDs 200 in the LED heater 150.

The groups 207 of LEDs 200 in the LED heater 150 and the resistive heating elements 209 in the resistive heater 151 are arranged in a non-overlapping manner. For example, the groups 207 of LEDs 200 in the LED heater 150 and the resistive heating elements 209 in the resistive heater 151 are arranged in an alternating (interleaved) pattern. That is, the groups 207 of LEDs 200 in the LED heater 150 and the resistive heating elements 209 in the resistive heater 151 are radially offset from each other. The groups 207 of LEDs 200 in the LED heater 150 and the resistive heating elements 209 in the resistive heater 151 extend radially from the ID of the base portion 132 of the pedestal 130 to the OD of the base portion 132 of the pedestal 130.

For example, each group 207 of LED strings may comprise one or more strings of LEDs 200 that extend radially from the ID of the base portion 132 of the pedestal 130 to the OD of the base portion 132 of the pedestal 130. Further, in each group 207 of LED strings, the one or more strings of LEDs 200 may be segmented and arranged in zones as shown and described below with reference to FIGS. 7A-7C. In each group 207 of LED strings, the segments and zones can be individually controlled as shown and described below with reference to subsequent figures. In some examples, the groups 207 of LED strings in the LED heater 150 can be divided into zones that radially overlap with each other as shown and described below with reference to FIGS. 7A-7C. Additionally, the resistive heating elements 203-1, 203-2, 203-3, 203-4 in the resistive heater 151 can also be individually controlled in combination with individually controlling the segments and zones in each group 207 of LED strings as shown and described below with reference to subsequent figures.

FIGS. 7A-7B show examples of arrangements of the LEDs 200 in the groups 205 and 207 described above. FIGS. 7A-7C show only a portion of one of the groups 205 and one of the groups 207. The following description applies to each of the groups 205 and 207. In FIG. 7A, the groups 205 and 207 of the LEDs 200 may comprise one or more strings of the LEDs 200. For example, three strings of the LEDs 200 are shown. However, any number of strings may be used. One or more of the strings of the LEDs 200 can be segmented as shown at 211, 213, 215, 217, 219. For example, the segment 215 overlaps the segments 211, 213, 217, 219. The LEDs 200 in the segment 215 can be controlled separately from the LEDs 200 in the segments 211, 213, 217, 219. The LEDs 200 in the segment 215 can be controlled in combination with the LEDs 200 in the segments 211, 213. The LEDs 200 in the segment 215 can be controlled in combination with the LEDs 200 in the segments 217, 219. Controlling the LEDs 200 in the segments 211, 213, 215, 217, 219 in this manner can provide the ability to finely heat the substrate 140 in combination with individually controlling the resistive heating elements 203, 209.

In FIGS. 7B and 7C, for example, each of the groups 205 and 207 of the LEDs 200 may comprise zones (e.g., two zones 221 and 223 shown in FIG. 7B and three zones 221, 223, 225 shown in FIG. 7C). For example, referring to FIGS. 4A-4C, 5, and 6, suppose that the group 205 (or 207) shown in FIG. 7B is the group 205-1 (or 207-1) and that the group 205 (or 207) shown in FIG. 7B is the group 205-2 (or 207-2). In this example, the zone 225 in the group 205-2 (or 207-2) will overlap the zones 221 and 223 in the group 205-1 (or 207-1). Further, while not shown to avoid cluttering the figures, the portions of the groups 205 and 207 shown in FIGS. 7B and 7C can be further segmented similar to the segmenting shown in FIG. 7A. Accordingly, in addition to the overlapping zones, the groups 205 and 207 of the LEDs 200 can also comprise overlapping segments. These segments and zones can be controlled individually or in any combination and further in combination with individually controlling the resistive heating elements 203, 209 to provide further granularity to finely heat the substrate 140.

The segments and zones described above can be formed in the LED heater 150 by electrically connecting the LEDs 200 and portions of the LED strings in different configurations as described above. For example, the connections can be hardwired on a printed circuit board (PCB) on which the LEDs 200 are arranged in the LED heater 150. Alternatively, the different connections and configurations of the LEDs 200 can be achieved using combinational logic circuits to form different segments and zones of the LEDs 200 in the LED heater 150. In some examples, the segmenting and zoning described above can also be achieved by controlling currents through the different portions of the LED heater 150.

### Second Example of Resistive and Radiative Heating

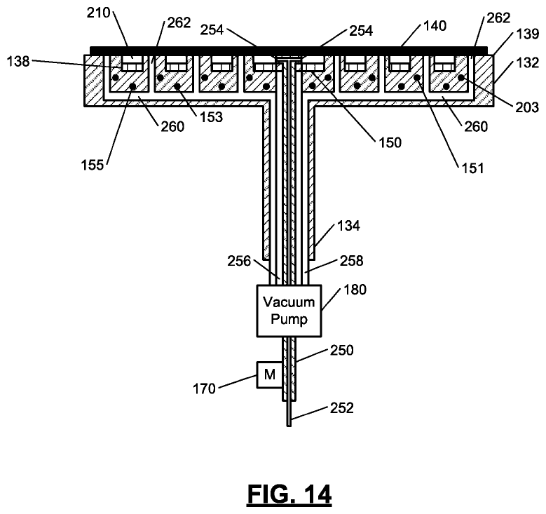

FIG. 8 schematically shows a second example of resistive and radiative heating according to the present disclosure. In the second example, the resistive heater 151 and the LED heater 150 are not collocated in the base portion 132 of the pedestal 130. Instead, the resistive heater 151 is disposed in the base portion 132 of the pedestal 130 and the LED heater 150 is arranged under and proximate to the base portion 132 of the pedestal 130. The LED heater 150 comprises a through hole 204 in the center region. The stem portion 134 of the pedestal 130 passes via the through hole 204. Since the resistive heater 151 and the LED heater 150 are not collocated in the base portion 132 of the pedestal 130, the pedestal 130 can comprise a ceramic material or a metallic material. The cooling channel 153 is arranged under the resistive heater 151 in the base portion 132 of the pedestal 130. The coolant from the coolant supply 160 (shown in FIG. 1A) flows through the cooling channel 153.

All of the various configurations and arrangements of the resistive heater 151 and the LED heater 150 shown and described above with reference to FIGS. 4A-7C for the first example can be implemented in the second example shown in FIG. 8 except that in the second example, the LED heater 150 is disposed under the base portion 132 of the pedestal 130 instead of being disposed in the base portion 132 of the pedestal 130. Therefore, the description of the various configurations and arrangements of the resistive heater 151 and the LED heater 150 for the first example is not repeated for the second example for brevity.

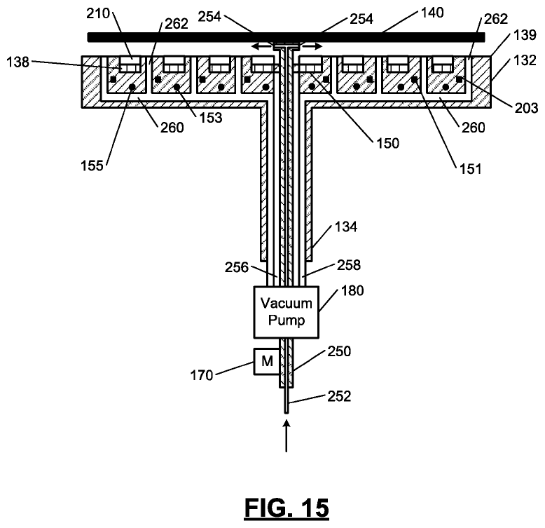

In addition to the different location, the LED heater 150 shown in FIG. 8 differs from the LED heater 150 shown in FIGS. 2-6 only in that the LED heater 150 in FIG. 8 additionally comprises lenses 231 as shown and described below with reference to FIG. 9. The LED heater 150 shown in FIG. 8 also comprises a window 210 (shown and described below with reference to FIG. 9). While not shown in FIGS. 2-6, the LED heater 150 shown in FIGS. 2-6 also comprises the window 210. Further, as described below, all of the LED heaters 150 described throughout the present disclosure comprise a PCB 201 on which the LEDs 200 and drivers 206 that drive the LEDs 200 (shown and described below with reference to FIG. 10) are arranged.

FIG. 9 schematically shows the LED heater 150 with the lenses 231. FIG. 9 shows a simplified cross-sectional view of the LED heater 150 with the lenses 231. Specifically, the LED heater 150 comprises the PCB 201 on which the LEDs 200 are arranged as shown and described above with reference to FIGS. 4A-7C. A lens array 233 comprising the lenses 231 is disposed on the LEDs 200. The lenses 231 in the lens array 233 are vertically aligned with the LEDs 200. In some examples, the lenses 231 may be built into (i.e., integrated with) the LEDs 200. That is, the LEDs 200 may be manufactured to integrally include the lenses 231 within the packaging of the LEDs 200. In other words, in some examples, each of the LEDs 200 may comprise a corresponding one of the lenses 231.

The window 210 is arranged on the lenses 231 (when the lenses 231 are used). For example, the window 210 may comprise an optically transparent, chemically resistant, and electrically insulating material such as quartz or sapphire. When the lenses 231 are not used (e.g., in the first and third examples), the window 210 is arranged on the LEDs 200. When the LED heater 150 shown in FIG. 9 is mounted under the base portion 132 of the pedestal 130 as shown in FIG. 8, the lenses 231 direct and focus the light emitted by the LEDs 200 onto the base portion 132 of the pedestal 130.

In the first and second examples described above, the LED heater 150 (specifically, the window 210, the PCB 201 of the LED heater 150, and the lens array 233 when used) comprise the through hole 204 in the center region. A diameter of the through hole 204 is less than or equal to a diameter of the stem portion 134 of the pedestal 130. For example, the diameter of the through hole 204 can be less than the diameter of the stem portion 134 of the pedestal 130 in the first example. The diameter of the through hole 204 is equal to the diameter of the stem portion 134 of the pedestal 130 in the second example.

The through hole 204 is provided so that a shaft (described below) can pass via stem portion 134 of the pedestal 130 and via the through hole 204 to move and rotate the substrate 140 (e.g., to raise the substrate 140 above the window 210 to purge the window 210 as described below). In implementations where the shaft is not used, providing the through hole 204 is unnecessary, and the LEDs 200 can be arranged throughout the LED heater from an OD of the LED heater 150 to the center of the LED heater 150.

The inner and outer peripheries of the window 210 are sealingly attached to the inner and outer peripheries of the LED heater 150, respectively. Accordingly, the LED heater 150 and the window 210 form a sealed enclosure in which the LEDs 200 and the PCB 201 are housed. Further, portions of the inside (e.g., base and sides) of the sealed enclosure can be shaped and/or equipped with reflective material (e.g., reflective rings) to reflect and/or direct the light emitted by the LEDs 200 onto the substrate 140 in the first example and onto the bottom of the base portion 132 of the pedestal 130 in the second example.

Since the window 210 (and the lenses 231 when used) is integrated with the LED heater 150 comprising the LEDs 200 and the drivers 206 disposed on the PCB 201, the entire assembly comprising the PCB 201, the LEDs 200, the drivers 206, the lenses 231 when used, and the window 210 is collectively called the LED heater 150.

FIG. 10 shows a top view of the LED heater 150. The lenses 231 are omitted to not clutter the figure and to clearly show the LEDs 200 and the drivers 206. Each driver 206 may control a set (group) of LEDs 200. For example, the drivers 206 can control the LEDs 200 in the segments, zones, and portions of the LED strings in the LED heater 150 as described above with reference to FIGS. 4A-7C in the first, second, and third examples. The controller 190 (shown in FIGS. 1A-1C) may control the LEDs 200 by controlling the drivers 206.

In FIG. 10, reference numerals 202 denote the LED strings arranged in the concentric pattern described above. While the LED strings 202 are shown as single strings for simplicity of illustration, each LED string shown at 202 can comprise a plurality of LED strings as shown in FIGS. 4A-4C. That is, the description of the LED strings 202, portions thereof (e.g., segments and zones), and control thereof is not limited to concentric arrangement of the LEDs 200 and also encompasses spoke-like arrangement of the LEDs 200. Further, the LEDs 200 in the LED strings 202 can be organized and controlled as segments, zones, and portions as described above. Further, in the third example, in which the LED heater 150 is disposed in the showerhead 120, the LED strings 202 can extend from the center of the LED heater 150 to the OD of the LED heater 150. That is, when disposed in the showerhead 120, the LED heater 150 can be fully populated with the LEDs 200. The LED heater 150 also does not comprise the through hole 204 when the LED heater 150 is disposed in the showerhead 120.

For example, after the substrate 140 is loaded into the processing chamber 101, the drivers 206 may supply power to the LEDs 200 at a first power level to preheat the substrate 140 while the substrate 140 is held above the pedestal 130 before the substrate 140 is lowered onto the pedestal 130 for depositing a film on the substrate 140. Subsequently, after a predetermined amount of time for which the substrate 140 is preheated, the drivers 206 may supply a reduced amount of power to the LEDs 200 at a second power level to heat the substrate 140 before or after the substrate 140 is lowered onto the pedestal 130. Subsequently, after the film is deposited on the substrate 140, the drivers 206 may supply a reduced amount of power to the LEDs 200 at a third power level before the substrate 140 is lifted off the pedestal 130 and removed from the processing chamber 101.

Additionally, in any of the steps described above, the drivers 206 may further control the power supplied to the LEDs 200. For example, each driver 206 may control a duty cycle (on/off times) of the respective LEDs 200. For example, each driver 206 may control the intensity (brightness) of the respective LEDs 200. For example, the controller 190 may control the drivers 206 such that only LEDs 202 in selected LED strings 202 or portions thereof are turned on or off at different times. For example, the controller 190 may control the drivers 206 such that only one or more LEDs 200 in a set (e.g., a zone or portion of the LED heater 150) are turned on or off at different times. For example, the controller 190 may control the drivers 206 such that the LEDs 200 or different portions of the LEDs 200 can output varying amounts of light (i.e., optical heating power) at different times. The drivers 206 may control the power supplied to the LEDs 200 gradually or in steps. Any combination of these and additional controls may be used to control the LEDs 200.

In some examples, a portion or the entirety of the control of the LEDs 200 provided by the controller 190 may be offloaded (in the form of hardware, firmware, or a combination thereof) into one or more drivers 206. In some examples, one or more drivers 206 may control the remaining drivers 206. The controller 190 and/or the drivers 206 can control the LEDs 200 differently before and after the substrate 140 is rotated. In addition to the control of the LEDs 200 described above, the controller 190 may control the resistive heater 151 in combination with the LED heater 150 as described above with reference to FIGS. 4A-7C in the first, second, and third examples. Further, the controller 190 may additionally control the rotation of the substrate 140 and the flow of the coolant from the coolant supply through the cooling channel 153. Thus, the combination of resistive and radiative (optical) heating of different portions of the substrate 140 can be controlled by controlling the resistive heater 151, the LED heater 150, the rotation of the substrate 140, and the flow of the coolant through the cooling channel 153.

### Third Example of Resistive and Radiative Heating

FIG. 11 shows a third example of resistive and radiative heating according to the present disclosure. In the third example, the resistive heater 151 and the LED heater 150 are not collocated in the base portion 132 of the pedestal 130. Instead, the resistive heater 151 is disposed in the base portion 132 of the pedestal 130 and the LED heater 150 is arranged in the showerhead 120 proximate to a faceplate 125 of the base portion 122 of the showerhead 120. The LED heater 150 disposed in the showerhead 120 is similar to the LED heater 150 disposed in the base portion 132 of the pedestal 130. The LED heater 150 disposed in the showerhead 120 comprises the PCB 201, the window 210, and the drivers 206 shown and described above with reference to FIGS. 8-10 except that the LED heater 150 disposed in the showerhead 120 does not comprise the lenses 231. The LED heater 150 disposed in the showerhead 120 also does not comprise the through hole 204. Further, the LED heater 150 disposed in the showerhead 120 is fully populated with the LEDs 200 from the center of the LED heater 150 to the OD of the LED heater 150. The layout of the LEDs 200 in the LED heater 150 disposed in the showerhead 120 can be any layout shown and described with reference to FIGS. 4A-4C, 5, 7A-7C or 10.

In the third example, the base portion 122 showerhead 120 comprises a plenum 235 defined by the faceplate 125, sidewall 129 and an upper surface 131 of the base portion 122 of the showerhead 120. The stem portion 124 of the showerhead comprises an inlet 133 through which one or more process gases are supplied to the showerhead 120 by the gas distribution system 102. A conduit (or a bore) 135 is drilled through a center of the stem portion 124 of the showerhead 120 from the inlet 133 to the plenum 235. The faceplate 125 comprises a plurality through holes 127.

The LED heater 150 is disposed within or under the plenum 235 in the base portion 124 of the showerhead 120. The window 210 of the LED heater 150 faces the substrate 140 and the pedestal 130. The window 210 of the LED heater 150 is coplanar with the faceplate 125 of the showerhead 120. In some examples, the faceplate 125 can be an annular ring, which along with the window 210 forms the faceplate 125 of the showerhead 120. Accordingly, the plenum 235 is defined by the upper surface 131 of the base portion 122 of the showerhead 120, the sidewall 129, and a bottom surface of the LED heater 150 that is opposite to the window 210.

The diameters of the LED heater 150 and the plenum 235 are less than an OD of the base portion 122 of the showerhead 120. The diameter of the LED heater 150 is equal to the diameter of the plenum 235. The LED heater 150 and the plenum 235 extend radially from the center of the base portion 122 of the showerhead 120 up to the OD of the base portion 122 of the showerhead 120. The diameters of the LED heater 150 and the plenum 235 are greater than or equal to a diameter of the substrate 140.

The through holes 127 extend vertically through the LED heater 150 (i.e., through the bottom surface of the LED heater 150, the PCB 201, and the window 210). The through holes 127 are parallel to a vertical axis of the showerhead 120 that is perpendicular to the diameter of the base portion 122 of the showerhead 120. The through holes 127 are distributed from the center of the base portion 122 of the showerhead 120 up to the OD of the base portion 122 of the showerhead 120. The through holes 127 are in fluid communication with the plenum 235, the conduit 135, and the inlet 133 of the showerhead 120. The LEDs 200 are arranged on the PCB 201 of the of the LED heater 150 interstitially with through holes 127 in the faceplate 125.

A cooling plate 157 is disposed on the upper surface 131 of the base portion 122 of the showerhead 120. The cooling plate 157 comprises one or more cooling channels 159. The coolant supplied by the coolant supply 160 (shown in FIG. 1C) flows through the cooling channels 159. The cooling plate 157 controls the temperature of the showerhead 120. The coolant flowing through the cooling channels 159 prevents the LED heater 150 in the showerhead 120 from overheating. The base portion 132 of the pedestal 130 also comprises the resistive hearer 151 and cooling channel 153. The coolant supplied by the coolant supply 160 (shown in FIG. 1C) also flows through the cooling channel 153.

All of the various configurations and arrangements of the resistive heater 151 and the LED heater 150 shown and described above with reference to FIGS. 4A-7C for the first example can be implemented in the second example shown in FIG. 8 except that in the third example, the LED heater 150 is disposed in the showerhead 120 instead of being disposed in the base portion 132 of the pedestal 130. Therefore, the description of the various configurations and arrangements of the resistive heater 151 and the LED heater 150 for the first and second examples is not repeated for the second example for brevity. Further, the various controls of the LED heater 150 and the resistive heater 151 for the first and second examples described above with reference to FIGS. 4A-10 apply to the third example and are therefore not repeated for the third example for brevity.

### Fourth Example of Resistive and Radiative Heating

FIG. 12 shows a fourth example of resistive and radiative heating used in the system 100 in FIG. 1D according to the present disclosure. In the fourth example, the resistive heater 151 and the first LED heater 150-1 are collocated in the base portion 132 of the pedestal 130 as shown and described above with reference to FIGS. 1A and 2-7C. The resistive heater 151 and the first LED heater 150-1 shown in FIG. 12 are identical to the resistive heater 151 and the LED heater 150 shown in FIGS. 1A and 2-7C, respectively, and are therefore not described again for brevity. Additionally, the second LED heater 150-2 disposed in the showerhead 120 is identical to the LED heater 150 disposed in the showerhead 120 as shown and described above with reference to FIG. 11 and is therefore not described again for brevity.

The geometries of the first and second LED heaters 150-1, 150-2 are identical to those of the LED heater 150 described above with reference to FIGS. 2-11 and below with reference to FIGS. 14 and 15 and are therefore not described again for brevity. The geometric relationships of the first and second LED heaters 150-1, 150-2 to the resistive heater 151, the pedestal 130, the components of the pedestal 130 (e.g., the base portion 132, the cooling channels 153 and 159, etc.), the showerhead 120, and the components of the showerhead 120 are identical to those of the LED heater 150 described above with reference to FIGS. 2-11 and below with reference to FIGS. 14 and 15 and are therefore not described again for brevity.

The second LED heater 150-2 can be controlled in the same manner as the first LED heater 150-1. The second LED heater 150-2 can be controlled in combination with the resistive heater 151 in the same manner as the first LED heater 150-1 can be controlled in combination with the resistive heater 151. The second LED heater 150-2 can be controlled in combination with the first LED heater 150-1 in any manner. The first and second LED heaters 150-1 and 150-2 can be controlled in combination with the resistive heater 151 in any manner. The various controls of the LED heater 150 and the resistive heater 151 for the first and third examples described above with reference to FIGS. 4A-11 and below with reference to FIGS. 14-34 apply to the fourth example and are therefore not repeated for the third example for brevity.

### Fifth Example of Resistive and Radiative Heating

FIG. 13 shows a fifth example of resistive and radiative heating used in the system 100 shown in FIG. 1E according to the present disclosure. In the fifth example, the resistive heater 151 is disposed in the base portion 132 of the pedestal 130 as shown and described above with reference to FIGS. 1A and 2-7C. The first LED heater 150-1 is disposed under the base portion 132 of the pedestal 130 as shown and described above with reference to FIGS. 8-10. The resistive heater 151 and the first LED heater 150-1 are identical to the resistive heater 151 and the LED heater 150 shown in FIGS. 8-10, respectively, and are therefore not described again for brevity. Additionally, the second LED heater 150-2 disposed in the showerhead 120 is identical to the LED heater 150 disposed in the showerhead 120 as shown and described above with reference to FIG. 11 and is therefore not described again for brevity.

Again, the geometries of the first and second LED heaters 150-1, 150-2 are identical to those of the LED heater 150 described above with reference to FIGS. 2-11 and below with reference to FIGS. 14 and 15 and are therefore not described again for brevity. The geometric relationships of the first and second LED heaters 150-1, 150-2 to the resistive heater 151, the pedestal 130, the components of the pedestal 130 (e.g., the base portion 132, the cooling channels 153 and 159, etc.), the showerhead 120, and the components of the showerhead 120 are identical to those of the LED heater 150 described above with reference to FIGS. 2-11 and below with reference to FIGS. 14 and 15 and are therefore not described again for brevity.

The second LED heater 150-2 can be controlled in the same manner as the first LED heater 150-1. The second LED heater 150-2 can be controlled in combination with the resistive heater 151 in the same manner as the first LED heater 150-1 can be controlled in combination with the resistive heater 151. The second LED heater 150-2 can be controlled in combination with the first LED heater 150-1 in any manner. The first and second LED heaters 150-1 and 150-2 can be controlled in combination with the resistive heater 151 in any manner. The various controls of the LED heater 150 and the resistive heater 151 for the second and third examples described above with reference to FIGS. 8-11 and below with reference to FIGS. 14-34 apply to the fifth example and are therefore not repeated for the third example for brevity.

### Example of Substrate Rotation and Window Purging

FIGS. 14 and 15 show an example of the LED heater 150 implemented in the pedestal 130 according to the first example described above with vacuum clamping used to clamp the substrate 140 to the pedestal 130. In addition, along with vacuum clamping, these figures show the purging and rotation schemes used to maintain the window 210 clean and to rotate the substrate 140 relative to the LED heater 150. FIG. 14 shows an example of vacuum clamping. FIG. 15 shows the purging of the window 210 when the substrate 140 is lifted from the pedestal 130 and is rotated. Elements already and shown and described above are not described again for brevity.

In FIG. 14, the LED heater 150 along with the window 210 is disposed in an annular cavity 138 formed in the base portion 132 of the pedestal 130. The annular cavity 138 is formed by removing material from the top surface of the base portion 132 of the pedestal 130. A depth of the annular cavity 138 is equal to a height of the LED heater 150 and the window 210. The LED heater 150 and the base portion 132 of the pedestal 130 are coplanar. Accordingly, a top surface of the window 210 is level with a top edge 139 of the base portion 132 of the pedestal 130. The substrate 140 is arranged on a top surface of the window 210 during processing. Vacuum clamping described below is used to clamp the substrate 140 to the pedestal 130.

The stem portion 134 of the pedestal 130 comprises a shaft 250. The shaft 250 extends through the centers of the stem portion 134 and the base portion 132 of the pedestal 130. The shaft 250 comprises a T-shaped end (i.e., a horizontal portion that forms the top of the T shape) and a distal end (i.e., a vertical portion that forms the bottom of the T shape). The T-shaped end of the shaft 250 extends via the through hole 204 in the LED heater 150 and a center region of the top surface of the base portion 132 of the pedestal 130. A top surface of the T-shaped end of the shaft 250 is level with top surface of the window 210. A bottom surface of the T-shaped end of the shaft 250 is level with and rests on top of the center region of the top surface of the base portion 132 of the pedestal 130. A diameter of the T-shaped end of the shaft 250 is slightly less than the diameter of the through hole 204 of the LED heater 150 and the through hole 204 in the LED heater 150.

The distal end of the shaft 250 extends through the resistive heater 151 and the cooling channel 153 and through the bottom end of the stem portion 134 of the pedestal 130. The distal end of the shaft 250 extends through the vacuum pump 180 attached to the bottom end of the stem portion 134 of the pedestal 130. One of the actuators 170 is attached to the distal end of the shaft 250. The actuator 170 can move the shaft 250 through the vacuum pump 180 and through the stem portion 134 and the base portion 132 of the pedestal 130 to lift and lower the substrate 140. In FIG. 15, when lifted, the substrate 140 is held by the T-shaped end of the shaft 250. When lifted, the actuator 170 can additionally rotate the shaft 250 to rotate the substrate 140 relative to the LED heater 150.

A conduit 252 is bored through the shaft 250. The conduit 252 and the shaft 250 are coaxial. The conduit 252 extends through the shaft 250 up to the T-shaped end of the shaft 250. The shaft 250 comprises a plurality of holes 254 bored radially through the T-shaped end of the shaft 250. Near the T-shaped end of the shaft 250, one end of the conduit 252 connects to the plurality of holes 254. A distal end of the conduit 252 extends out of the distal end of the shaft 250. The distal end of the conduit 252 is connected to one of the gas sources 104 through the valve 152 (shown in FIG. 1A). In FIG. 15, when the shaft 250 lifts the substrate 140, a purge gas is supplied through the conduit 252. The purge gas flows through the conduit 252, flows out through the holes 254, and flows radially across and over the window 210 in the direction of the arrows shown to clean the window 210.

The stem portion 134 of the pedestal 130 further comprises a conduit 256 through which electrical connections (e.g., insulated wires or conductors) to the electrical elements in the base portion 132 of the pedestal 130 (e.g., the resistive heater 151 and the LED heater 150) are routed. The distal ends of the electrical connections are connected to the controller 190 (shown in FIG. 1A). The conduit 256 is bored through and extends through the stem portion 134 of the pedestal 130. The conduit 256 extends into the base portion 132 of the pedestal 130, through the resistive heater 151 and the cooling channel 153, up to the through hole 204 of the LED heater 150. The conduits 252, 256 and the shaft 250 are coaxial. A diameter of the conduit 256 is greater than the diameter of the shaft 250.

The stem portion 134 of the pedestal 130 further comprises a conduit 258. A diameter of the conduit 258 is greater than the diameter of the conduit 256 and less than the diameter of the stem portion 134 of the pedestal 130. The conduits 258, 252, 256 and the shaft 250 are coaxial. A first end of the conduit 258 is in fluid communication with the vacuum pump 180. A second end of the conduit 258 extends through the stem portion 134 of the pedestal 130 and into the base portion 132 of the pedestal 130. The second end of the conduit 258 extends into the base portion 132 of the pedestal 130 up to a point below the cooling channel 153. At the second end, the conduit 258 connects to a first set of conduits (or passages) 260 bored radially through the base portion 132 of the pedestal 130. The conduits 260 extend radially up to the OD of the base portion 132 of the pedestal 130. The conduits 260 are in fluid communication with the conduit 258.

A second set of conduits 262 is bored perpendicularly to the first set of conduits 260 through the base portion 132 of the pedestal 130. The conduits 262 extend from the conduits 260 through the cooling channel 153, the resistive heater 151, and the LED heater 150 up to the top surface of the base portion 132 of the pedestal 130 on which the substrate 140 rests during processing. The conduits 262 are in fluid communication with the conduits 260, 258.

When the substrate 140 is to be clamped to the pedestal 130, the controller 190 activates the vacuum pump 180 and opens the valve 184 (shown in FIG. 1A) to create vacuum in the conduits 258, 260, 262. The vacuum in the conduits 258, 260, 262 clamps the substrate 140 to the base portion 132 of the pedestal 130. After the substrate 140 is clamped to the base portion 132 of the pedestal 130, the controller 190 controls the resistive heater 151, the LED heater 150, and the cooling channel 153 to heat the substrate 140 as described above according to the process to be performed on the substrate 140.

In FIG. 15, when the substrate 140 needs to be rotated relative to the LED heater 150, the controller 190 controls the vacuum pump 180 and the valve 184 such that the vacuum in the conduits 258, 260, 262 is reduced. The vacuum in the conduits 258, 260, 262 is sufficiently reduced to allow the shaft 250 to counter the force of the vacuum and to lift the substrate 140. The controller 190 activates the actuator 170 such that the shaft 250 lifts and rotates the substrate 140. In some applications, the substrate 140 can be lifted and held stationary and the pedestal 130 can be rotated so as to rotate the LED heater 150 relative to the substrate 140.

When the substrate 140 is lifted, the controller 190 opens the valve 152 (shown in FIG. 1A) to allow the purge gas to flow through the conduit 252 and through the holes 254. The purge gas flows through the conduit 252 and the holes 254 radially over and across the window 210 as shown by arrows in FIG. 15. The flow of the purge gas over and across the window 210 removes any material that may be deposited on the window 210. The controller 190 controls the valves 152 and 184 (shown in FIG. 1A) such that the vacuum pump 180 continues suction though the conduits 258, 260, 262 and through the processing chamber 101 (shown in FIG. 1A). Accordingly, the material removed from the window 210 is evacuated from the processing chamber 101.

Subsequently, the actuator 170 lowers the shaft 250 to place the substrate 140 again on the base portion 132 of the pedestal 130. The substrate 140 is then vacuum clamped as described above. The controller 190 again controls the resistive heater 151, the LED heater 150, and the cooling channel 153 to heat the substrate 140 as described above. The procedure is repeated as needed until the processing of the substrate 140 is complete.

In FIGS. 14 and 15, the rotation of the substrate 140 and the purging of the window 210 of the LED heater 150 are described with reference to the LED heater 150 and the resistive heater 151 arranged in the concentric pattern shown and described above with reference to FIGS. 4A-4C. The substrate 140 can be lifted and rotated and the window 210 of the LED heater 150 can be purged in a similar manner when the LED heater 150 and the resistive heater 151 are arranged as shown and described with reference to FIGS. 5 and 6. The substrate 140 can be lifted and rotated and the window 210 of the first LED heater 150-1 can be purged in a similar manner when the first LED heater 150-1 and the resistive heater 151 are arranged as shown and described with reference to FIG. 12. Further, the substrate 140 can be lifted and rotated in a similar manner when the LED heater 150 is arranged under the base portion 132 of the pedestal 130 as shown and described with reference to FIG. 8 and when the LED heater 150 is arranged in the showerhead 120 as shown and described with reference to FIG. 11. Furthermore, the substrate 140 can be lifted and rotated in a similar manner when the first LED heater 150-1 is arranged under the base portion 132 of the pedestal 130 as shown and described with reference to FIG. 13 and when the second LED heater 150-2 is arranged in the showerhead 120 as shown and described with reference to FIG. 13.

Further, in FIGS. 14 and 15, vacuum clamping is shown and described as an example of a clamping mechanism used to clamp the substrate 140 to the base portion 132 of the pedestal. Instead, any other clamping mechanism may be used. Non-limiting examples of other clamping mechanisms comprise electrostatic clamping and mechanical clamping that can be employed in the pedestal 130.

Furthermore, while not shown, in some examples, instead of using a clamping scheme, mesas can be used to support the substrate 140 on the pedestal 130. In the first example, where the resistive heater 151 and the LED heater 150 are collocated in the base portion 132 of the pedestal 130, the mesas are tiny bumps or generally cylindrical elements that are raised above the top surface of the window 210 projecting towards the substrate 140. The mesas can be formed integrally (i.e., homogenously) on the top surface of the window 210. The mesas comprise the same optically transparent, chemically resistant, and electrically insulating material such as quartz or sapphire as the window 210. The mesas can be distributed anywhere on the top surface of the window 210 interstitially with the LEDs 200 (e.g., between the LEDs 200).

In the third example, where the resistive heater 151 is disposed in the base portion 132 of the pedestal 130 and the LED heater 150 is disposed in the showerhead 120, the mesas are tiny bumps or generally cylindrical elements that are raised above the top surface of the base portion 132 of the pedestal 130. The mesas can be formed integrally (i.e., homogenously) on the top surface of the base portion 132 of the pedestal 130. The mesas comprise the same material as the base portion 132 of the pedestal 130. The mesas can be distributed anywhere on the top surface of the base portion 132 of the pedestal 130. In the first and third examples, the number, size, and shapes of the mesas can vary. The mesas can be circular, square, hexagonal, or any other polygonal shape (or any combination thereof).

FIG. 16 shows an example of a system for controlling the resistive heater 151, the LED heater 150, the first and second LED heaters 150-1 and 150-2, and the cooling channels 153 and 159 in the first through fifth examples of resistive and radiative heating described above. The controller 190 controls the resistive heater 151, the LED heater 150, the first and second LED heaters 150-1 and 150-2, and the cooling channels 153 and 159 as described above with reference to FIGS. 2-15 and as described below in further detail with reference to FIGS. 15-34. The controller 190 and the drivers 206 perform the controlling operations described above with reference to FIGS. 2-15 and the methods described below with reference to FIGS. 15-34.

Briefly, in the first through fifth examples of resistive and radiative heating described above, the controller 190 controls the drivers 206, which in turn control the LEDs 200 in different portions (e.g., segments and zones) of the LED heaters 150, 150-1, 150-2 as described above and below. The controller 190 also controls the resistive heating elements 203 and 207 of the resistive heater 151 as described above and below. The controller 190 controls the different portions (e.g., segments and zones) of the LED heaters 150, 150-1, 150-2 and different ones of the resistive heating elements 203 and 207 of the resistive heater 151 in a temporally staggered manner as described in further detail below. Additionally, the controller 190 rotates the substrate 140 as described above and below. Further, the controller 190 controls the flow of the coolant supplied by the coolant supply 160 through the cooling channels 153 and 159 as described above and below. The controller 190 can perform all of these controlling operations in combination to fine tune the heating of the substrate 140 using any combination of these controls.

In the following description, for generality, only the names of the individual components of the resistive heater 151 and the LED heaters 150, 150-1, 150-2 are used and the reference numerals for the individual components of the resistive heater 151 and the LED heaters 150, 150-1, 150-2 are omitted. Further, the methods described below apply to resistive and radiative heating of the substrate 140 using any of the first through fifth examples of resistive and radiative heating described above.

### Methods of Resistive and Radiative Heating

FIG. 17 shows a method 300 of resistive and radiative heating of the substrate 140 according to the present disclosure. At 302, the substrate 140 is heated using resistive heating (also called coarse heating) provided by the resistive heater 151 disposed in the base portion 132 of the pedestal 130. At 304, the substrate 140 is heated using radiative heating (also called fine-tuned heating) provided by the LED heater 150 disposed in the base portion 132 of the pedestal 130, under the pedestal 130, or in the showerhead 120. The methods of combining the coarse heating and the fine-tuned heating provided by controlling the resistive heater 151 and the LED heater 150 are described below in detail. In all of the following methods, while not shown, in combination with controlling the resistive heater 151 and the LED heater 150, the controller 190 also controls the flow of the coolant through the cooling channels 153, 159 to control the temperature of the substrate 140, the showerhead 120, and the LED heater 150.

FIG. 18 shows a method 310 of resistive and radiative heating of the substrate 140 including substrate rotation according to the present disclosure. At 312, the substrate 140 is heated using resistive heating provided by the resistive heater 151 disposed in the base portion 132 of the pedestal 130. At 314, the controller 190 actuates the shaft 250 and rotates the substrate 140. At 316, the controller 190 adjusts currents supplied to the resistive heating elements of the resistive heater 151. Additionally, the controller 190 and/or the drivers 206 adjust magnitudes of illumination of different portions (e.g., segments and/or zones described above) of the LED heater 150. For example, the controller 190 controls different combinations of the resistive heating elements of the resistive heater 151 and the segments and/or zones of the LED heater 150. These various controls of the resistive heater 151 and the LED heater 150 minimize cold spots in the substrate 140, increase the temperature uniformity across the substrate 140, and reduce excessive heating of the LEDs 200 in the LED heater 150.

FIG. 19 shows a method 320 of resistive and radiative heating of the substrate 140 including substrate rotation according to the present disclosure. At 322, the substrate 140 is heated using resistive heating provided by the resistive heater 151 disposed in the base portion 132 of the pedestal 130. At 324, the controller 190 selects a first portion (e.g., a first zone) of the LED heater 150 to heat the substrate 140. At 326, the controller 190 actuates the shaft 250 and rotates the substrate 140. At 328, the controller 190 deselects the first portion and selects a second portion (e.g., a second zone) of the LED heater 150 to heat the substrate 140.

In this manner, the controller 190 can rotate the substrate 140 again and select different portions of the LED heater 150 to heat the substrate 140. Selecting different portions of the LED heater 150 to heat the substrate 140 at different times while also periodically rotating the substrate 140 minimizes cold spots in the substrate 140, increases the temperature uniformity across the substrate 140, and reduces excessive heating of the LEDs 200 in the LED heater 150.

FIG. 20 shows a method 340 of resistive and radiative heating of the substrate 140 including substrate rotation according to the present disclosure. At 342, the controller 190 selects a first set of resistive heating elements of the resistive heater 151 disposed in the base portion 132 of the pedestal 130 to heat the substrate 140. At 344, the controller 190 selects a first portion (e.g., a first zone) of the LED heater 150 to heat the substrate 140. At 346, the controller 190 actuates the shaft 250 and rotates the substrate 140. At 348, the controller 190 deselects the first set of resistive heating elements of the resistive heater 151 and the first portion of the LED heater 150 and selects a second set of resistive heating elements of the resistive heater 151 and a second portion (e.g., a second zone) of the LED heater 150 to heat the substrate 140.

In this manner, the controller 190 can rotate the substrate 140 again and select and deselect different sets of resistive heating elements of the resistive heater 151 and different portions of the LED heater 150 to heat the substrate 140. Selecting different sets of resistive heating elements of the resistive heater 151 and different portions of the LED heater 150 to heat the substrate 140 at different times while also periodically rotating the substrate 140 minimizes cold spots in the substrate 140, increases the temperature uniformity across the substrate 140, and reduces excessive heating of the LEDs 200 in the LED heater 150.

FIG. 21 shows a method 360 of resistive and radiative heating of the substrate 140 including substrate rotation according to the present disclosure. At 362, the substrate 140 is heated using resistive heating provided by the resistive heater 151 disposed in the base portion 132 of the pedestal 130. At 364, the controller 190 selects a portion (e.g., a first zone) of the LED heater 150 to heat the substrate 140. The controller 190 controls the selected portion (e.g., the first zone) of the LED heater 150 to heat the substrate 140 with a first magnitude of illumination of the LEDs 200 in the selected portion. At 366, the controller 190 actuates the shaft 250 and rotates the substrate 140. At 368, the controller 190 controls the selected portion (e.g., the first zone) of the LED heater 150 to heat the substrate 140 with a second magnitude of illumination of the LEDs 200 in the selected portion.

In this manner, the controller 190 can rotate the substrate 140 again and change the magnitude of illumination of the selected portion of the LED heater 150 to heat the substrate 140. Selecting different magnitudes of illumination of the selected portion of the LED heater 150 to heat the substrate 140 at different times while also periodically rotating the substrate 140 minimizes cold spots in the substrate 140, increases the temperature uniformity across the substrate 140, and reduces excessive heating of the LEDs 200 in the LED heater 150.

FIG. 22 shows a method 380 of resistive and radiative heating of the substrate 140 including substrate rotation according to the present disclosure. At 382, the substrate 140 is heated using resistive heating provided by the resistive heater 151 disposed in the base portion 132 of the pedestal 130. At 384, the controller 190 selects first and second portions (e.g., first and second zones) of the LED heater 150 to heat the substrate 140. The controller 190 controls the selected portions (e.g., the first and second zones) of the LED heater 150 to heat the substrate 140 with first and second magnitudes of illumination of the LEDs 200 in the first and second portions, respectively. At 386, the controller 190 actuates the shaft 250 and rotates the substrate 140. At 388, the controller 190 controls the selected portions (e.g., the first and second zones) of the LED heater 150 to heat the substrate 140 with third and fourth magnitudes of illumination of the LEDs 200 in the selected portions.

In this manner, the controller 190 can rotate the substrate 140 again and change the magnitudes of illumination of the selected portions of the LED heater 150 to heat the substrate 140. Selecting different magnitudes of illumination of the selected portions of the LED heater 150 to heat the substrate 140 at different times while also periodically rotating the substrate 140 minimizes cold spots in the substrate 140, increases the temperature uniformity across the substrate 140, and reduces excessive heating of the LEDs 200 in the LED heater 150.

FIG. 23 shows a method 400 of resistive and radiative heating of the substrate 140 including substrate rotation according to the present disclosure. At 402, the controller 190 selects first and second sets of resistive heating elements (e.g., first and second resistive heating elements) of the resistive heater 151 disposed in the base portion 132 of the pedestal 130 to heat the substrate 140. The controller 190 controls the selected resistive heating elements (e.g., the first and second resistive heating elements) of the resistive heater 151 to heat the substrate 140 by supplying first and second currents to the first and second sets of resistive heating elements, respectively.

At 404, the controller 190 selects first and second portions (e.g., first and second zones) of the LED heater 150 to heat the substrate 140. The controller 190 controls the selected portions (e.g., the first and second zones) of the LED heater 150 to heat the substrate 140 with first and second magnitudes of illumination of the LEDs 200 in the first and second portions, respectively. At 406, the controller 190 actuates the shaft 250 and rotates the substrate 140.

At 408, the controller 190 controls the selected resistive heating elements (e.g., the first and second resistive heating elements) of the resistive heater 151 to heat the substrate 140 by supplying third and fourth currents to the first and second sets of resistive heating elements, respectively. The controller 190 controls the selected portions (e.g., the first and second zones) of the LED heater 150 to heat the substrate 140 with third and fourth magnitudes of illumination of the LEDs 200 in the first and second portions, respectively.

In this manner, the controller 190 can rotate the substrate 140 again, change the currents supplied to the selected resistive heating elements of the resistive heater 151, and change the magnitudes of illumination of the selected portions of the LED heater 150 to heat the substrate 140. Supplying different currents to the selected resistive heating elements of the resistive heater 151 at different times and selecting different magnitudes of illumination of the selected portions of the LED heater 150 to heat the substrate 140 at different times while also periodically rotating the substrate 140 minimizes cold spots in the substrate 140, increases the temperature uniformity across the substrate 140, and reduces excessive heating of the LEDs 200 in the LED heater 150.

FIG. 24 shows a method 420 of resistive and radiative heating of the substrate 140 including substrate rotation according to the present disclosure. At 422, the controller 190 selects first and second sets of resistive heating elements (e.g., first and second resistive heating elements) of the resistive heater 151 disposed in the base portion 132 of the pedestal 130 to heat the substrate 140. The controller 190 controls the selected resistive heating elements (e.g., the first and second resistive heating elements) of the resistive heater 151 to heat the substrate 140 by supplying first and second currents to the first and second sets of resistive heating elements, respectively.

At 424, the controller 190 selects first and second portions (e.g., first and second zones) of the LED heater 150 to heat the substrate 140. The controller 190 controls the selected portions (e.g., the first and second zones) of the LED heater 150 to heat the substrate 140 with first and second magnitudes of illumination of the LEDs 200 in the first and second portions, respectively. At 426, the controller 190 actuates the shaft 250 and rotates the substrate 140.

At 428, the controller 190 controls the selected resistive heating elements (e.g., the first and second resistive heating elements) of the resistive heater 151 to heat the substrate 140 by supplying third and fourth currents to the first and second sets of resistive heating elements, respectively. The controller 190 controls the selected portions (e.g., the first and second zones) of the LED heater 150 to heat the substrate 140 with third and fourth magnitudes of illumination of the LEDs 200 in the first and second portions, respectively.

At 430, the controller 190 deselects the first set of resistive heating elements of the resistive heater 151 and the first portion of the LED heater 150 and selects a third set of resistive heating elements of the resistive heater 151 and a third portion (e.g., a third zone) of the LED heater 150 to heat the substrate 140. At 432, the controller 190 controls the selected resistive heating elements (e.g., the second and third resistive heating elements) of the resistive heater 151 to heat the substrate 140 by supplying second and third current to the second and third sets of resistive heating elements, respectively. The controller 190 controls the selected portions (e.g., the second and third zones) of the LED heater 150 to heat the substrate 140 with second and third magnitudes of illumination of the LEDs 200 in the second and third portions, respectively. In step 432, the controller 190 can also change the current supplied to the second set of resistive heating elements and change the magnitude of illumination of the LEDs 200 in the second portion.

In this manner, the controller 190 can rotate the substrate 140 again, select and deselect different sets of resistive elements of the resistive heater 151, change the currents supplied to the selected resistive heating elements of the resistive heater 151, select and deselect different portions of the LED heater 150, and change the magnitudes of illumination of the selected portions of the LED heater 150 to heat the substrate 140. Selecting different sets of resistive heating elements of the resistive heater 151 at different times, supplying different currents to the selected different sets of resistive heating elements of the resistive heater 151 at different times, selecting different portions of the LED heater 150 at different times, and selecting different magnitudes of illumination of the selected different portions of the LED heater 150 to heat the substrate 140 at different times while also periodically rotating the substrate 140 minimizes cold spots in the substrate 140, increases the temperature uniformity across the substrate 140, and reduces excessive heating of the LEDs 200 in the LED heater 150.

FIG. 25 shows a method 440 of resistive and radiative heating of the substrate 140 according to the present disclosure. At 442, the substrate 140 is heated using resistive heating (also called coarse heating) provided by the resistive heater 151 disposed in the base portion 132 of the pedestal 130. At 444, the substrate 140 is heated using radiative heating (also called fine-tuned heating) provided by the LED heater 150 disposed under the base portion 132 of the pedestal 130. The methods of combining the coarse heating and the fine-tuned heating provided by controlling the resistive heater 151 and the LED heater 150, which are described above in detail, also apply when the resistive heater 151 disposed in the base portion 132 of the pedestal 130 and the LED heater 150 disposed under the base portion 132 of the pedestal 130. In all of the above methods, while not shown, in combination with controlling the resistive heater 151 and the LED heater 150, the controller 190 also controls the flow of the coolant through the cooling channels 153, 159 to control the temperature of the substrate 140 and the LED heater 150.

FIG. 26 shows a method 460 of resistive and radiative heating of the substrate 140 including substrate rotation according to the present disclosure. At 462, the substrate 140 is heated using resistive heating provided by the resistive heater 151 disposed under the base portion 132 of the pedestal 130. At 464, the controller 190 actuates the shaft 250 and rotates the substrate 140. At 466, the controller 190 adjusts currents supplied to the resistive heating elements of the resistive heater 151. Additionally, the controller 190 and/or the drivers 206 adjust magnitudes of illumination of different portions (e.g., segments and/or zones described above) of the LED heater 150 as described in the above methods. For example, the controller 190 controls different combinations of the resistive heating elements of the resistive heater 151 and the segments and/or zones of the LED heater 150 as described in the above methods. These various controls of the resistive heater 151 and the LED heater 150 minimize cold spots in the substrate 140, increase the temperature uniformity across the substrate 140, and reduce excessive heating of the LEDs 200 in the LED heater 150.

FIG. 27 shows a method 500 of resistive and radiative heating of the substrate 140 according to the present disclosure. At 502, the substrate 140 is heated using resistive heating (also called coarse heating) provided by the resistive heater 151 disposed in the base portion 132 of the pedestal 130. At 504, the substrate 140 is heated using radiative heating (also called fine-tuned heating) provided by the first LED heater 150-1 disposed in the base portion 132 of the pedestal 130 or under the pedestal 130, and/or by the second LED heater 150-2 disposed in the showerhead 120. The methods of combining the coarse heating and the fine-tuned heating provided by controlling the resistive heater 151 and the first and second LED heaters 150-1, 150-2 are described below in detail.

In all of the following methods, while not shown, in combination with controlling the resistive heater 151 and the first and second LED heaters 150-1, 150-2, the controller 190 also controls the flow of the coolant through the cooling channels 153, 159 to control the temperature of the substrate 140, the showerhead 120, and the first and second LED heaters 150-1, 150-2. Further, in the following methods, the descriptions of the first and second LED heaters 150-1, 150-2 can be interchanged (i.e., the first LED heater 150-1 can be read in place of the second LED heater 150-2 and vice versa).

FIG. 28 shows a method 510 of resistive and radiative heating of the substrate 140 including substrate rotation according to the present disclosure. At 512, the substrate 140 is heated using resistive heating provided by the resistive heater 151 disposed in the base portion 132 of the pedestal 130. At 514, the controller 190 actuates the shaft 250 and rotates the substrate 140. At 516, the controller 190 adjusts currents supplied to the resistive heating elements of the resistive heater 151. Additionally, the controller 190 and/or the drivers 206 adjust magnitudes of illumination of different portions (e.g., segments and/or zones described above) of the first and second LED heaters 150-1, 150-2. For example, the controller 190 controls different combinations of the resistive heating elements of the resistive heater 151 and the segments and/or zones of the first and second LED heaters 150-1, 150-2. These various controls of the resistive heater 151 and the first and second LED heaters 150-1, 150-2 minimize cold spots in the substrate 140, increase the temperature uniformity across the substrate 140, and reduce excessive heating of the LEDs 200 in the first and second LED heaters 150-1, 150-2.

FIG. 29 shows a method 520 of resistive and radiative heating of the substrate 140 including substrate rotation according to the present disclosure. At 522, the substrate 140 is heated using resistive heating provided by the resistive heater 151 disposed in the base portion 132 of the pedestal 130. At 524, the controller 190 selects a first portion (e.g., a first zone) of the first LED heater 150-1 to heat the substrate 140. At 526, the controller 190 actuates the shaft 250 and rotates the substrate 140. At 528, the controller 190 deselects the first portion of the first LED heater 150-1 and selects a second portion (e.g., a second zone) of the second LED heater 150-2 to heat the substrate 140.

While not shown, the controller 190 can also alternatingly activate and deactivate the first and second LED heaters 150-1, 150-2. Further, the controller 190 can alter the time durations for which the first and second LED heaters 150-1, 150-2 are activated and deactivated. The controller 190 can control the first and second LED heaters 150-1, 150-2 in this manner while also controlling the resistive heater 151 and rotating the substrate 140 as described throughout the present disclosure.

In this manner, the controller 190 can rotate the substrate 140 again and select different portions of the first and second LED heaters 150-1, 150-2 to heat the substrate 140. Selecting different portions of the first and second LED heaters 150-1, 150-2 to heat the substrate 140 at different times while also periodically rotating the substrate 140 minimizes cold spots in the substrate 140, increases the temperature uniformity across the substrate 140, and reduces excessive heating of the LEDs 200 in the first and second LED heaters 150-1, 150-2.

FIG. 30 shows a method 540 of resistive and radiative heating of the substrate 140 including substrate rotation according to the present disclosure. At 542, the controller 190 selects a first set of resistive heating elements of the resistive heater 151 disposed in the base portion 132 of the pedestal 130 to heat the substrate 140. At 544, the controller 190 selects a first portion (e.g., a first zone) of the first LED heater 150-1 to heat the substrate 140. At 546, the controller 190 actuates the shaft 250 and rotates the substrate 140. At 548, the controller 190 deselects the first set of resistive heating elements of the resistive heater 151 and the first portion of the first LED heater 150-1 (or the second LED heater 150-2) and selects a second set of resistive heating elements of the resistive heater 151 and a second portion (e.g., a second zone) of the second LED heater 150-2 to heat the substrate 140.

In this manner, the controller 190 can rotate the substrate 140 again and select and deselect different sets of resistive heating elements of the resistive heater 151 and different portions of the first and second LED heaters 150-1, 150-2 to heat the substrate 140. Selecting different sets of resistive heating elements of the resistive heater 151 and different portions of the first and second LED heaters 150-1, 150-2 to heat the substrate 140 at different times while also periodically rotating the substrate 140 minimizes cold spots in the substrate 140, increases the temperature uniformity across the substrate 140, and reduces excessive heating of the LEDs 200 in the first and second LED heaters 150-1, 150-2.

FIG. 31 shows a method 560 of resistive and radiative heating of the substrate 140 including substrate rotation according to the present disclosure. At 562, the substrate 140 is heated using resistive heating provided by the resistive heater 151 disposed in the base portion 132 of the pedestal 130. At 564, the controller 190 selects a first portion (e.g., a first zone) of the first LED heater 150-1 and a second portion (e.g., a second zone) of the second LED heater 150-1 to heat the substrate 140. The first portion (e.g., the first zone) of the first LED heater 150-1 and the second portion (e.g., the second zone) of the second LED heater 150-1 may be overlapping or non-overlapping. The controller 190 controls the selected portions (e.g., the first zone of the first LED heater 150-1 and the second zone of the second LED heater 150-2) to heat the substrate 140 with first and second magnitudes of illumination of the LEDs 200 in the selected portions, respectively. At 566, the controller 190 actuates the shaft 250 and rotates the substrate 140. At 568, the controller 190 controls the selected portions (e.g., the first zone of the first LED heater 150-1 and the second zone of the second LED heater 150-2) to heat the substrate 140 with second and first magnitudes of illumination of the LEDs 200 in the selected portions, respectively.

In this manner, the controller 190 can rotate the substrate 140 again and can change the magnitudes of illumination of the LEDs 200 in the selected portions of the first and second LED heaters 150-1, 150-2 to heat the substrate 140. Selecting different magnitudes of illumination of the selected portions of the first and second LED heaters 150-1, 150-2 to heat the substrate 140 at different times while also periodically rotating the substrate 140 minimizes cold spots in the substrate 140, increases the temperature uniformity across the substrate 140, and reduces excessive heating of the LEDs 200 in the first and second LED heaters 150-1, 150-2.

FIG. 32 shows a method 580 of resistive and radiative heating of the substrate 140 including substrate rotation according to the present disclosure. At 582, the substrate 140 is heated using resistive heating provided by the resistive heater 151 disposed in the base portion 132 of the pedestal 130. At 584, the controller 190 selects first and second portions (e.g., first and second zones) of the first LED heater 150-1 to heat the substrate 140 without altering a state of the second LED heater 150-2 (i.e., leaving the second LED heater 150-2 partially or fully on or off). The controller 190 controls the selected portions (e.g., the first and second zones) of the first LED heater 150-1 to heat the substrate 140 with first and second magnitudes of illumination of the LEDs 200 in the first and second portions, respectively. At 586, the controller 190 actuates the shaft 250 and rotates the substrate 140. At 588, the controller 190 controls the selected portions (e.g., the first and second zones) of the first LED heater 150-1 to heat the substrate 140 with third and fourth magnitudes of illumination of the LEDs 200 in the selected portions without altering the state of the second LED heater 150-2.

In this manner, the controller 190 can rotate the substrate 140 again and can change the magnitudes of illumination of the LEDs 200 in the selected portions of the first LED heater 150-1 to heat the substrate 140 without altering the state of the second LED heater 150-2. Selecting different magnitudes of illumination of the selected portions of the first LED heater 150-1 to heat the substrate 140 at different times while also periodically rotating the substrate 140 and not altering the state of the second LED heater 150-2 minimizes cold spots in the substrate 140, increases the temperature uniformity across the substrate 140, and reduces excessive heating of the LEDs 200 in the first LED heater 150-1.

FIG. 33 shows a method 600 of resistive and radiative heating of the substrate 140 including substrate rotation according to the present disclosure. At 602, the controller 190 selects first and second sets of resistive heating elements (e.g., first and second resistive heating elements) of the resistive heater 151 disposed in the base portion 132 of the pedestal 130 to heat the substrate 140. The controller 190 controls the selected resistive heating elements (e.g., the first and second resistive heating elements) of the resistive heater 151 to heat the substrate 140 by supplying first and second currents to the first and second sets of resistive heating elements, respectively.

At 604, the controller 190 selects first and second portions (e.g., first and second zones) of the first and second LED heaters 150-1, 150-2 to heat the substrate 140, respectively. The controller 190 controls the selected portions (e.g., the first and second zones) of the first and second LED heaters 150-1, 150-2 to heat the substrate 140 with first and second magnitudes of illumination of the LEDs 200 in the first and second portions, respectively. At 606, the controller 190 actuates the shaft 250 and rotates the substrate 140.

At 608, the controller 190 controls the selected resistive heating elements (e.g., the first and second resistive heating elements) of the resistive heater 151 to heat the substrate 140 by supplying third and fourth currents to the first and second sets of resistive heating elements, respectively. The controller 190 controls the selected portions (e.g., the first and second zones) of the first and second LED heaters 150-1, 150-2 to heat the substrate 140 with third and fourth magnitudes of illumination of the LEDs 200 in the first and second portions, respectively.

In this manner, the controller 190 can rotate the substrate 140 again, change the currents supplied to the selected resistive heating elements of the resistive heater 151, and change the magnitudes of illumination of the selected portions of the first and second LED heaters 150-1, 150-2 to heat the substrate 140. Supplying different currents to the selected resistive heating elements of the resistive heater 151 at different times and selecting different magnitudes of illumination of the selected portions of the first and second LED heaters 150-1, 150-2 to heat the substrate 140 at different times while also periodically rotating the substrate 140 minimizes cold spots in the substrate 140, increases the temperature uniformity across the substrate 140, and reduces excessive heating of the LEDs 200 in the first and second LED heaters 150-1, 150-2.

FIG. 34 shows a method 620 of resistive and radiative heating of the substrate 140 including substrate rotation according to the present disclosure. At 622, the controller 190 selects first and second sets of resistive heating elements (e.g., first and second resistive heating elements) of the resistive heater 151 disposed in the base portion 132 of the pedestal 130 to heat the substrate 140. The controller 190 controls the selected resistive heating elements (e.g., the first and second resistive heating elements) of the resistive heater 151 to heat the substrate 140 by supplying first and second currents to the first and second sets of resistive heating elements, respectively.

At 624, the controller 190 selects first and second portions (e.g., first and second zones) of the first and second LED heaters 150-1, 150-2 to heat the substrate 140. The controller 190 controls the selected portions (e.g., the first and second zones) of the first and second LED heaters 150-1, 150-2 to heat the substrate 140 with first and second magnitudes of illumination of the LEDs 200 in the first and second portions, respectively. At 426, the controller 190 actuates the shaft 250 and rotates the substrate 140.

At 628, the controller 190 controls the selected resistive heating elements (e.g., the first and second resistive heating elements) of the resistive heater 151 to heat the substrate 140 by supplying third and fourth currents to the first and second sets of resistive heating elements, respectively. The controller 190 controls the selected portions (e.g., the first and second zones) of the first and second LED heaters 150-1, 150-2 to heat the substrate 140 with third and fourth magnitudes of illumination of the LEDs 200 in the first and second portions, respectively.

At 630, the controller 190 deselects the first set of resistive heating elements of the resistive heater 151 and the first portion of the first LED heater 150-1 and selects a third set of resistive heating elements of the resistive heater 151 and a third portion (e.g., a third zone) of the first LED heater 150-1 to heat the substrate 140. At 632, the controller 190 controls the selected resistive heating elements (e.g., the second and third resistive heating elements) of the resistive heater 151 to heat the substrate 140 by supplying second and third current to the second and third sets of resistive heating elements, respectively. The controller 190 controls the selected portions (e.g., the second and third zones) of the second and first LED heaters 150-2, 150-1 to heat the substrate 140 with second and third magnitudes of illumination of the LEDs 200 in the second and third portions, respectively. In step 632, the controller 190 can also change the current supplied to the second set of resistive heating elements of the resistive heater 151 and change the magnitude of illumination of the LEDs 200 in the second portion of the second LED heater 150-2.

In this manner, the controller 190 can rotate the substrate 140 again, select and deselect different sets of resistive elements of the resistive heater 151, change the currents supplied to the selected resistive heating elements of the resistive heater 151, select and deselect different portions of the first and second LED heaters 150-1, 150-2, and change the magnitudes of illumination of the selected portions of the first and second LED heaters 150-1, 150-2 to heat the substrate 140. Selecting different sets of resistive heating elements of the resistive heater 151 at different times, supplying different currents to the selected different sets of resistive heating elements of the resistive heater 151 at different times, selecting different portions of the first and second LED heaters 150-1, 150-2 at different times, and selecting different magnitudes of illumination of the selected different portions of the first and second LED heaters 150-1, 150-2 to heat the substrate 140 at different times while also periodically rotating the substrate 140 minimizes cold spots in the substrate 140, increases the temperature uniformity across the substrate 140, and reduces excessive heating of the LEDs 200 in the first and second LED heaters 150-1, 150-2.

The methods of combining the coarse heating, the fine-tuned heating provided by controlling the resistive heater 151, the LED heater 150, the first and second LED heaters 150-1 and 150-2, and substrate rotation, which are described above in detail, also apply when the resistive heater 151 is disposed in the base portion 132 of the pedestal 130 and the LED heater 150 is disposed under the base portion 132 of the pedestal 130 and when the resistive heater 151 and the first and second LED heaters 150-1 and 150-2 are disposed as shown and described above with reference to FIGS. 12 and 13, as described in the above methods. Further, in all of the above methods, while not shown, in combination with controlling the resistive heater 151, the LED heater 150, and the first and second LED heaters 150-1 and 150-2, the controller 190 also controls the flow of the coolant through the cooling channels 153, 159 to control the temperature of the substrate 140, the showerhead 120, and the LED heater 150.

Thus, the systems and methods of the present disclosure provide various ways to combine resistive and radiative (LED) heating to minimize or eliminate cold spots on the substrate 140 and to increase temperature uniformity across the substrate 140. The resistive heater 151 provides coarse heating and the LED heater 150 and the first and second LED heaters 150-1 and 150-2 supplement the resistive heater 151 by providing fine-tuned heating as described above. When the resistive and LED heaters 151, 150, 150-1 are collocated in the pedestal 130 as in the first and fourth examples, controlling (turning on and off as well as modulating power supplied to) different portions of the resistive and LED heaters 151, 150, 150-1 at different times (i.e., in a temporally staggered manner) in combination with substrate rotation prevents overheating of the radiative heaters 151, 150, 150-1. The overheating of the LED heaters 150, 150-1 can be further reduced by separating the LED heater 150 from the resistive heater 151 and locating the LED heaters 150, 150-1 under the pedestal 130 as in the second and fifth examples or by separating the LED heater 150 from the resistive heater 151 and locating the LED heaters 150, 150-2 in the showerhead 120 as in the third and fourth examples. Furthermore, the overheating of the LED heaters 150, 150-1 can be prevented in the second and fourth examples by controlling different portions of the resistive and LED heaters 151, 150, 150-1 in a temporally staggered manner in combination with substrate rotation as in the first example. The overheating of the LED heater 150-1 can be prevented in the fourth and fifth examples by controlling different portions of the resistive and LED heaters 151, 150-1, 150-2 in a temporally staggered manner in combination with substrate rotation similarly as in the first example.

In addition to preventing overheating of the LED heater 150, 150-1, 150-2 in the first through fifth examples, controlling different portions of the resistive and LED heaters 151, 150, 150-1, 150-2 in a temporally staggered manner in combination with substrate rotation further minimizes or eliminates cold spots on the substrate 140 and increases temperature uniformity across the substrate 140. The cooling channels 153, 159 are also provided in the pedestal 130 and the showerhead 120 to further control the temperatures of the pedestal 130 and the showerhead 120, to further prevent the overheating of the LED heater 150, and to further improve the temperature uniformity of the substrate 140.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a metal plating chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a pedestal configured to support a substrate;
a resistive heater disposed in the pedestal, wherein the resistive heater is configured to heat the substrate; and
a radiative heater disposed in the pedestal, wherein the radiative heater is configured to heat the substrate.

2. The substrate processing system of claim 1 wherein:
the resistive heater comprises one or more resistive heating elements; and
the radiative heater comprises a plurality of optical elements.

3. The substrate processing system of claim 2 wherein the optical elements comprise light emitting diodes.

4. The substrate processing system of claim 1 wherein:
the pedestal comprises a base portion and a stem portion; and
the resistive heater and the radiative heater are disposed in the base portion of the pedestal.

5. The substrate processing system of claim 4 wherein the base portion is cylindrical and wherein the resistive heater and the radiative heater extend from a center region of the base portion towards an outer diameter of the base portion.

6. The substrate processing system of claim 4 wherein:
the radiative heater is disposed proximate to a surface of the base portion on which the substrate is arranged; and
the resistive heater is disposed under the radiative heater in the base portion.

7. The substrate processing system of claim 4 wherein the resistive and radiative heaters are coplanar.

8. The substrate processing system of claim 4 wherein:
the base portion of the pedestal is cylindrical;
the resistive heater comprises a plurality of resistive heating elements arranged in first concentric circles in the base portion;
the radiative heater comprises a plurality of optical elements arranged in second concentric circles in the base portion; and
the first and second concentric circles are interleaved with each other and extend from a center region of the base portion towards an outer diameter of the base portion.

9. The substrate processing system of claim 8 wherein:
the radiative heater is disposed proximate to a surface of the base portion on which the substrate is arranged; and
the resistive heater is disposed under the radiative heater in the base portion.

10. The substrate processing system of claim 8 wherein the resistive and radiative heaters are coplanar.

11. The substrate processing system of claim 4 wherein:
the base portion of the pedestal is cylindrical;
the resistive heater comprises a plurality of resistive heating elements arranged in concentric circles in the base portion;
the radiative heater comprises a plurality of optical elements arranged in radially extending spokes in the base portion; and
the concentric circles and the radially extending spokes extend from a center region of the base portion towards an outer diameter of the base portion.

12. The substrate processing system of claim 11 wherein:
the radiative heater is disposed proximate to a surface of the base portion on which the substrate is arranged; and
the resistive heater is disposed under the radiative heater in the base portion.

13. The substrate processing system of claim 4 wherein:
the base portion of the pedestal is cylindrical;
the resistive heater comprises a plurality of resistive heating elements arranged in first radially extending spokes in the base portion;
the radiative heater comprises a plurality of optical elements arranged in second radially extending spokes in the base portion; and
the first and second radially extending spokes are interleaved with each other and extend from a center region of the base portion towards an outer diameter of the base portion.

14. The substrate processing system of claim 13 wherein:
the radiative heater is disposed proximate to a surface of the base portion on which the substrate is arranged; and
the resistive heater is disposed under the radiative heater in the base portion.

15. The substrate processing system of claim 14 wherein the resistive and radiative heaters are coplanar.

16. The substrate processing system of claim 4 further comprising a cooling channel disposed in the base portion under the resistive and radiative heaters.

17. The substrate processing system of claim 4 wherein the resistive heater comprises a plurality of resistive heating elements and the radiative heater comprises a plurality of optical elements, the substrate processing system further comprising a controller configured to control different ones of the resistive heating elements and different ones of the optical elements in a temporally staggered manner.

18. The substrate processing system of claim 17 further comprising:
a shaft disposed through the stem portion and the base portion; and
an actuator coupled to the shaft,
wherein the controller is configured to move the substrate relative to the pedestal.

19. The substrate processing system of claim 4 wherein the radiative heater comprises:
a plurality of optical elements arranged on a printed circuit board (PCB);
one or more drivers arranged on the PCB, wherein the one or more drivers is configured to control the optical elements; and
a window covering the optical elements, the window being optically transparent and sealingly attached to the PCB.

20. The substrate processing system of claim 19 wherein the pedestal further comprises:
a shaft disposed through centers of the stem portion, the base portion, and the PCB, wherein the shaft comprises a conduit configured to receive a gas and a plurality of holes in fluid communication with the conduit near a first end of the shaft proximate to the radiative heater; and
an actuator coupled to a second end of the shaft, wherein the actuator is configured to move the substrate perpendicularly relative to a plane in which the base portion lies,
wherein the plurality of holes supply the gas radially over the window when the shaft is raised above the window.

21. The substrate processing system of claim 1 wherein:
the pedestal comprises a base portion and a stem portion;
the resistive heater is disposed in the base portion of the pedestal; and
the radiative heater is disposed under the base portion and around the stem portion proximate to the base portion.

22. The substrate processing system of claim 21 wherein the base portion is cylindrical and wherein the resistive heater and the radiative heater extend from a center region of the base portion towards an outer diameter of the base portion.

23. The substrate processing system of claim 21 wherein the radiative heater comprises:
a plurality of optical elements arranged on a printed circuit board (PCB);
one or more drivers arranged on the PCB, wherein the one or more drivers is configured to control the optical elements;
a plurality of lenses disposed on the optical elements; and
a window covering the optical elements and the lenses, the window being optically transparent and sealingly attached to the PCB.

24. The substrate processing system of claim 21 wherein:
the base portion of the pedestal is cylindrical;
the resistive heater comprises a plurality of resistive heating elements arranged in first concentric circles in the base portion;
the radiative heater comprises a plurality of optical elements arranged in second concentric circles in the base portion; and
the first and second concentric circles are interleaved with each other and extend from a center region of the base portion towards an outer diameter of the base portion.

25. The substrate processing system of claim 21 wherein:
the base portion of the pedestal is cylindrical;
the resistive heater comprises a plurality of resistive heating elements arranged in concentric circles in the base portion;
the radiative heater comprises a plurality of optical elements arranged in radially extending spokes in the base portion; and
the concentric circles and the radially extending spokes extend from a center region of the base portion towards an outer diameter of the base portion.

26. The substrate processing system of claim 21 wherein:
the base portion of the pedestal is cylindrical;
the resistive heater comprises a plurality of resistive heating elements arranged in first radially extending spokes in the base portion;
the radiative heater comprises a plurality of optical elements arranged in second radially extending spokes in the base portion; and
the first and second radially extending spokes are interleaved with each other and extend from a center region of the base portion towards an outer diameter of the base portion.

27. The substrate processing system of claim 21 further comprising a cooling channel disposed in the base portion under the resistive heater.

28. The substrate processing system of claim 21 wherein the resistive heater comprises a plurality of resistive heating elements and the radiative heater comprises a plurality of optical elements, the substrate processing system further comprising a controller configured to control different ones of the resistive heating elements and different ones of the optical elements in a temporally staggered manner.

29. The substrate processing system of claim 28 further comprising:
a shaft disposed through the stem portion and the base portion; and
an actuator coupled to the shaft,
wherein the controller is configured to move the substrate relative to the pedestal.

30-97. (canceled)
